(19) United States
(12) Patent Application Publication
(10) Pub. No.: US 2026/0171012 A1
(43) Pub. Date: Jun. 18, 2026

(54) Display Substrate, Drive Method and Manufacturing Method Thereof, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Zhongman ZHAO, Beijing (CN); Zhenglong YAN, Beijing (CN); Yanyang SHANG, Beijing (CN); Ling SHI, Beijing (CN); Qi WEI, Beijing (CN)

(21) Appl. No.: 18/712,724

(22) PCT Filed: Aug. 23, 2023
(86) PCT No.: PCT/CN2023/114500

§ 371 Date: May 23, 2024

(51) Int. Cl. G09G 3/3233; H10K 59/131

(52) U.S. Cl. CPC G09G 3/3233; H10K 59/131; G09G 2300/0426; G09G 2300/0465; G09G 2300/0819; G09G 2300/0842; G09G 2300/0861; G09G 2310/08; G09G 2320/0233; G09G 2320/0247; G09G 2320/043; G09G 2330/021

(57) ABSTRACT

A display substrate, a drive method and a manufacturing method thereof, and a display apparatus are disclosed. The display substrate includes multiple circuit units, the circuit units at least includes a pixel drive circuit, the pixel drive circuit at least includes a data writing transistor connected to a data signal line; the plurality of circuit units at least comprise a first circuit unit and a second circuit unit, the first circuit unit includes a first pixel drive circuit, the second circuit unit includes a second pixel drive circuit, the first pixel drive circuit and the second pixel drive circuit share a same data writing transistor and are connected to a same data signal line, and the data signal line sequentially provides a first data signal to the first pixel drive circuit and a second data signal to the second pixel drive circuit through the data writing transistor.

### CROSS-REFERENCE TO RELATED APPLICATIONS

The present application is a U.S. National Phase Entry of International Application PCT/CN2023/114500 having an international filing date of Aug. 23, 2023, and entitled “Display Substrate, Drive Method and Manufacturing Method Thereof, and Display Apparatus”, contents of which are hereby incorporated herein by reference in their entireties.

### TECHNICAL FIELD

The present disclosure relates to, but is not limited to, the field of display technologies, and particularly to a display substrate, a drive method and a manufacturing method thereof, and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With constant development of display technologies, a display apparatus (Flexible Display) in which an OLED or a QLED is used as a light emitting device and signal control is performed through a Thin Film Transistor (TFT) has become a mainstream product in the field of display at present.

### SUMMARY

The following is a summary of subject matter described herein in detail. The summary is not intended to limit the scope of protection of the claims.

In one aspect, the present disclosure provides a display substrate including a plurality of circuit units constituting a plurality of unit rows and a plurality of unit columns, at least one circuit unit at least includes a pixel drive circuit, at least one of the pixel drive circuits at least includes a data writing transistor connected to a data signal line; the plurality of circuit units at least include a first circuit unit and a second circuit unit adjacent in a unit row direction, the first circuit unit includes a first pixel drive circuit, the second circuit unit includes a second pixel drive circuit, the first pixel drive circuit and the second pixel drive circuit share a same data writing transistor and are connected to a same data signal line, the data signal line provides a first data signal to the first pixel drive circuit and provides a second data signal to the second pixel drive circuit sequentially through the data writing transistor.

In an exemplary implementation mode, an orthographic projection of the data writing transistor on a plane of the display substrate at least partially overlaps with an orthographic projection of a unit dividing line on the plane of the display substrate, and an orthographic projection of the data signal line on the plane of the display substrate at least partially overlaps with an orthographic projection of the unit dividing line on the plane of the display substrate, the unit dividing line is a straight line located between the first circuit unit and the second circuit unit and extending in a unit column direction.

In an exemplary implementation mode, the data writing transistor at least includes a data writing active layer, the data signal line is connected to a first region of the data writing active layer through a data connection electrode, an orthographic projection of the data writing active layer on the plane of the display substrate at least partially overlaps with the orthographic projection of the unit dividing line on the plane of the display substrate, and an orthographic projection of the data connection electrode on the plane of the display substrate at least partially overlaps with the orthographic projection of the unit dividing line on the plane of the display substrate.

In an exemplary implementation mode, in a direction perpendicular to the display substrate, the display substrate includes a plurality of conductive layers sequentially disposed on a base substrate, the data signal line and the data connection electrode are disposed in different conductive layers, the data signal line is connected to the data connection electrode through a first connection via, and an orthographic projection of the first connection via on the plane of the display substrate at least partially overlaps with the orthographic projection of the unit dividing line on the plane of the display substrate.

In an exemplary implementation mode, in the direction perpendicular to the display substrate, the display substrate further includes a first semiconductor layer in which the data writing active layer is disposed, the data connection electrode is connected to the first region of the data writing active layer through a second connection via, an orthographic projection of the second connection via on the plane of the display substrate at least partially overlaps with the orthographic projection of the unit dividing line on the plane of the display substrate.

In an exemplary implementation mode, the display substrate further includes a first control signal line and a second control signal line; the first control signal line is connected to the first pixel drive circuit, the first control signal line is configured such that the data signal line provides the first data signal to the first pixel drive circuit; the second control signal line is connected to the second pixel drive circuit, and the second control signal line is configured such that the data signal line provides the second data signal to the second pixel drive circuit.

In an exemplary implementation mode, the first pixel drive circuit further includes a first compensation transistor and a first drive transistor, the second pixel drive circuit further includes a second compensation transistor and a second drive transistor, and the data writing transistor is connected to a first electrode of the first drive transistor and a first electrode of the second drive transistor respectively; a gate electrode of the first compensation transistor is connected to the first control signal line, a first electrode of the first compensation transistor is connected to a gate electrode of the first drive transistor, and a second electrode of the first compensation transistor is connected to a second electrode of the first drive transistor; a gate electrode of the second compensation transistor is connected to the second control signal line, a first electrode of the second compensation transistor is connected to a gate electrode of the second drive transistor, and a second electrode of the second compensation transistor is connected to a second electrode of the second drive transistor.

In an exemplary implementation mode, the display substrate includes a plurality of conductive layers sequentially disposed on a base substrate in the direction perpendicular to the display substrate, and the first control signal line and the second control signal line are disposed in a same conductive layer.

In an exemplary implementation mode, the data writing transistor, the first drive transistor and the second drive transistor are polysilicon transistors, and the first compensation transistor and the second compensation transistor are oxide transistors.

In an exemplary implementation mode, each pixel drive circuit further includes a light emitting control transistor, the first pixel drive circuit and the second pixel drive circuit share a same light emitting control transistor, a first electrode of the light emitting control transistor is connected to a first power supply line, and a second electrode of the light emitting control transistor is connected to a second electrode of the data writing transistor.

In an exemplary implementation mode, the light emitting control transistor at least includes a light emitting control active layer, the first power supply line is connected to a first region of the light emitting control active layer through a power supply connection electrode, an orthographic projection of the light emitting control active layer on a plane of the display substrate at least partially overlaps with the orthographic projection of the unit dividing line on the plane of the display substrate, and an orthographic projection of the power supply connection electrode on the plane of the display substrate at least partially overlaps with the orthographic projection of the unit dividing line on the plane of the display substrate.

In an exemplary implementation mode, in the direction perpendicular to the display substrate, the display substrate includes a plurality of conductive layers sequentially disposed on the base substrate, the first power supply line and the power supply connection electrode are disposed in different conductive layers, the first power supply line is connected to the power supply connection electrode through a third connection via which is disposed in the first circuit unit and the second circuit unit respectively.

In an exemplary implementation mode, the pixel drive circuit further includes an initialization transistor, the first pixel drive circuit and the second pixel drive circuit share a same initialization transistor, a first electrode of the initialization transistor is connected to an initial signal line, and a second electrode of the initialization transistor is connected to a second electrode of the data writing transistor.

In an exemplary implementation mode, the initialization transistor at least includes an initialization active layer, a first region of the initialization active layer is connected to the initial signal line, and a second electrode of the initialization transistor is connected to a second electrode of the data writing transistor through an initial connection electrode, an orthographic projection of the initial connection electrode on the plane of the display substrate at least partially overlaps with the orthographic projection of the unit dividing line on the plane of the display substrate.

In an exemplary implementation mode, in a direction perpendicular to the display substrate, the display substrate further includes a first semiconductor layer, the initialization active layer is disposed in the first semiconductor layer, the initial connection electrode is connected to an active layer of the data writing transistor through a fourth connection via, and an orthographic projection of fourth connection via on the plane of the display substrate at least partially overlaps with the orthographic projection of the unit dividing line on the plane of the display substrate.

In another aspect, the present disclosure further provides a display apparatus, including the display substrate described above.

In another aspect, the present disclosure further provides a drive method of a display substrate including a plurality of circuit units constituting a plurality of unit rows and a plurality of unit columns, at least one of the circuit units at least includes a pixel drive circuit, at least one pixel drive circuit at least includes a data writing transistor connected to a data signal line; the plurality of circuit units at least include a first circuit unit and a second circuit unit adjacent in a unit row direction, the first circuit unit includes a first pixel drive circuit, the second circuit unit includes a second pixel drive circuit, the first pixel drive circuit and the second pixel drive circuit share a same data writing transistor and a same data signal line; and the drive method includes:
the data signal line provides a first data signal to the first pixel drive circuit and a second data signal to the second pixel drive circuit through the data writing transistor sequentially.

In an exemplary implementation mode, the display substrate further includes a first control signal line and a second control signal line; the first pixel drive circuit further includes a first compensation transistor, a first drive transistor and a first storage capacitor, a gate electrode of the first compensation transistor is connected to the first control signal line, a first electrode of the first compensation transistor is respectively connected to a gate electrode of the first drive transistor and the first storage capacitor, a second electrode of the first compensation transistor is connected to a second electrode of the first drive transistor, a first electrode of the first drive transistor is connected to the data writing transistor; the second pixel drive circuit further includes a second compensation transistor, a second drive transistor and a second storage capacitor, a gate electrode of the second compensation transistor is connected to the second control signal line, a first electrode of the second compensation transistor is respectively connected to a gate electrode of the second drive transistor and the second storage capacitor, a second electrode of the second compensation transistor is connected to a second electrode of the second drive transistor, a first electrode of the second drive transistor is connected to the data writing transistor.

In an exemplary implementation mode, the data signal line provides the first data signal to the first pixel drive circuit and provides the second data signal to the second pixel drive circuit through the data writing transistor sequentially, including:
the first control signal line provides a turned-on signal, the second control signal line provides a turned-off signal, the first compensation transistor is turned on to initialize the first storage capacitor;
the first control signal line provides a turned-off signal, the second control signal line provides a turned-on signal, the second compensation transistor is turned on to initialize the second storage capacitor;
the first control signal line provides a turned-on signal, the second control signal line provides a turned-off signal, the first compensation transistor is turned on, and the data signal line provides the first data signal to the first storage capacitor through the data writing transistor, the first drive transistor, and the first compensation transistor; and
the first control signal line provides a turned-off signal, the second control signal line provides a turned-on signal, the second compensation transistor is turned on, and the data signal line provides the second data signal to the second storage capacitor through the data writing transistor, the second drive transistor, and the second compensation transistor.

In an exemplary implementation mode, the data signal line provides the first data signal to the first pixel drive circuit and provides the second data signal to the second pixel drive circuit through the data writing transistor sequentially, including:
the first control signal line provides a turned-on signal, the second control signal line provides a turned-off signal, the first compensation transistor is turned on to initialize the first storage capacitor;
the first control signal line provides a turned-on signal, the second control signal line provides a turned-off signal, the first compensation transistor is turned on, and the data signal line provides the first data signal to the first storage capacitor through the data writing transistor, the first drive transistor, and the first compensation transistor;
the first control signal line provides a turned-off signal, the second control signal line provides a turned-on signal, the second compensation transistor is turned on to initialize the second storage capacitor; and
the first control signal line provides a turned-off signal, the second control signal line provides a turned-on signal, the second compensation transistor is turned on, and the data signal line provides the second data signal to the second storage capacitor through the data writing transistor, the second drive transistor, and the second compensation transistor.

In an exemplary implementation mode, the data signal line provides the first data signal to the first pixel drive circuit and provides the second data signal to the second pixel drive circuit through the data writing transistor sequentially, including:
the first control signal line provides a turned-on signal, the second control signal line provides a turned-off signal, the first compensation transistor is turned on to initialize the first storage capacitor;
the first control signal line provides a turned-on signal, the second control signal line provides a turned-on signal, the first compensation transistor is turned on to initialize the first storage capacitor, the second compensation transistor is turned on to initialize the second storage capacitor;
the first control signal line provides a turned-on signal, the second control signal line provides a turned-on signal, the first compensation transistor is turned on, the data signal line provides the first data signal to the first storage capacitor through the data writing transistor, the first drive transistor and the first compensation transistor, the second compensation transistor is turned on, the data signal line provides the first data signal to the second storage capacitor through the data writing transistor, the second drive transistor and the second compensation transistor; and
the first control signal line provides a turned-off signal, the second control signal line provides a turned-on signal, the second compensation transistor is turned on, and the data signal line provides the second data signal to the second storage capacitor through the data writing transistor, the second drive transistor, and the second compensation transistor.

In another aspect, the present disclosure further provides a manufacturing method of a display substrate, the display substrate including a plurality of circuit units constituting a plurality of unit rows and a plurality of unit columns, at least one of the circuit units at least includes a pixel drive circuit, at least one pixel drive circuit at least includes a data writing transistor connected to a data signal line, the plurality of circuit units at least include a first circuit unit and a second circuit unit adjacent in a unit row direction; and the manufacturing method includes:
forming a first pixel drive circuit in the first circuit unit, forming a second pixel drive circuit in the second circuit unit, wherein the first pixel drive circuit and the second pixel drive circuit share a same data writing transistor and a same data signal line, the data signal line provides a first data signal to the first pixel drive circuit and provides a second data signal to the second pixel drive circuit through the data writing transistor sequentially.

Other aspects of the present disclosure may be comprehended after the drawings and the detailed descriptions are read and understood.

### BRIEF DESCRIPTION OF DRAWINGS

Accompany drawings are used to provide further understanding of technical solution of the present disclosure, and form a part of the description. The accompany drawings and embodiments of the present disclosure are adopted to explain the technical solution of the present disclosure, and do not form limitations on the technical solution of the present disclosure.

FIG. 1 is a schematic diagram of a structure of a display apparatus.

FIG. 2 is a schematic diagram of a planar structure of a display substrate.

FIG. 3 is a schematic diagram of a sectional structure of a display substrate.

FIG. 4 is an equivalent circuit diagram of a pixel drive circuit according to an exemplary embodiment of the present disclosure.

FIG. 5 is a schematic diagram of a planar structure of a display substrate according to an exemplary embodiment of the present disclosure.

FIG. 6 is a schematic diagram of connection between pixel drive circuits and signal lines according to an exemplary embodiment of the present disclosure.

FIG. 7 is a schematic diagram of a display substrate after a pattern of a first semiconductor layer is formed according to the present disclosure.

FIGS. 8A and 8B are schematic diagrams of a display substrate after a pattern of a first conductive layer is formed according to the present disclosure.

FIGS. 9A and 9B are schematic diagrams of a display substrate after a pattern of a second conductive layer is formed according to the present disclosure.

FIG. 10A and FIG. 10B are schematic diagrams of a display substrate after a pattern of a second semiconductor layer is formed according to the present disclosure.

FIGS. 11A and 11B are schematic diagrams of a display substrate after a pattern of a third conductive layer is formed according to the present disclosure.

FIG. 12 is a schematic diagram of a display substrate after a pattern of a sixth insulation layer is formed according to the present disclosure.

FIG. 13A and FIG. 13B are schematic views of a display substrate after a pattern of a fourth conductive layer is formed according to the present disclosure.

FIG. 14 is a schematic diagram of a display substrate after a pattern of a first planarization layer is formed according to the present disclosure.

FIG. 15A and FIG. 15B are schematic diagrams of a display substrate after a pattern of a fifth conductive layer is formed according to the present disclosure.

FIG. 16 is a schematic diagram of a display substrate after a pattern of a second planarization layer is formed according to the present disclosure.

FIG. 17 is a schematic diagram of a display substrate after a pattern of an anode conductive layer is formed according to the present disclosure.

FIG. 18 is a driving timing diagram of a pixel drive circuit according to an exemplary embodiment of the present disclosure.

FIG. 19 is another driving timing diagram of a pixel drive circuit according to an exemplary embodiment of the present disclosure.

FIG. 20 is another driving timing diagram of a pixel drive circuit according to an exemplary embodiment of the present disclosure.

Reference signs are described as follows.

| | | |
|---|---|---|
| 11-First active layer; | 12-Second active layer; | 13-Third active layer; |
| 14-Fourth active layer; | 15-Fifth active layer; | 16-Sixth active layer; |
| 17-Seventh active layer; | 18- Eighth active layer; | 21-First scan signal line; |
| 22-Second scan signal line | 23-Third scan signal line; | 24-Light emitting signal line; |
| 31-First shielding line; | 32-Second shielding line; | 41-First initial signal line; |
| 42-Second initial signal line; | 43-Third initial signal line; | 51-First connection electrode; |
| 52-Second connection electrode | 53-Third connection electrode; | 54-Fourth connection electrode; |
| 55-Fifth connection electrode; | 56-Sixth connection electrode; | 57-Seventh connection electrode; |
| 58-Eighth connection electrode; | 59-Ninth connection electrode; | 61-First power supply line; |
| 62-Data signal line; | 63-Anode connection electrode; | 71-First plate; |
| 72-Second plate; | 73-Opening; | 74-Plate connection strip; |
| 81-First control line; | 82-Second control line; | 101-Base substrate; |
| 102-Drive circuit layer; | 103-Light emitting structure layer; | 104-Encapsulation structure layer. |

### DETAILED DESCRIPTION

To make the objectives, technical solutions, and advantages of the present disclosure clearer, the embodiments of the present disclosure will be described in detail below in with reference to the accompany drawings. It is to be noted that the implementation modes may be implemented in various forms. Those of ordinary skills in the art can easily understand such a fact that implementation modes and contents may be transformed into various forms without departing from the purpose and scope of the present disclosure. Therefore, the present disclosure should not be explained as being limited to the contents recorded in the following implementations modes only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one implementation mode of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the composition elements may be changed as appropriate according to a direction according to which each composition element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or detachable connection, or integral connection; it may be mechanical connection or electrical connection; it may be direct connection, or indirect connection through an intermediate, or internal communication between two elements. Those of ordinary skills in the art can understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In cases that transistors with opposite polarities are used, or a current direction changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “electrical connection” includes connection of composition elements through an element with a certain electrical action. An “element with a certain electrical action” is not particularly limited as long as electric signals between the connected composition elements can be sent and received. Examples of the “element with the certain electrical action” not only include an electrode and a line, but also include a switch element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive thin film” sometimes. Similarly, an “insulation thin film” may be replaced with an “insulation layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

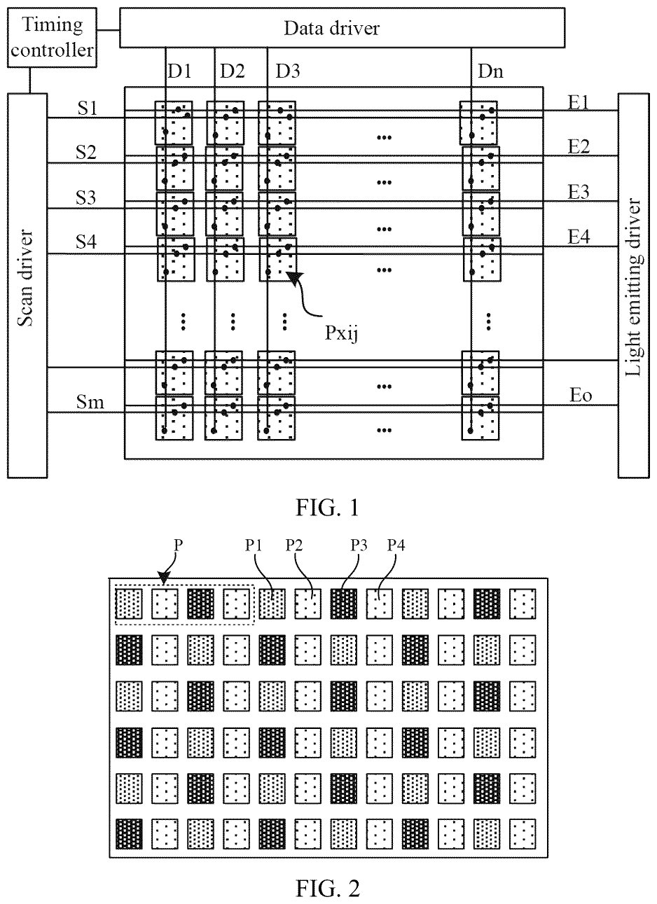

FIG. 1 is a schematic diagram of a structure of a display apparatus. As shown in FIG. 1, the display apparatus may include a timing controller, a data driver, a scan driver, a light emitting driver, and a pixel array. The timing controller is connected to the data driver, the scan driver, and the light emitting driver respectively. The data driver is connected to a plurality of data signal lines (D1 to Dn) respectively. The scan driver is connected to a plurality of scan signal lines (S1 to Sm) respectively. The light emitting driver is connected to a plurality of light emitting signal lines (E1 to Eo) respectively. The pixel array may include a plurality of sub-pixels Pxij, i and j may be natural numbers. At least one of the sub-pixels Pxij may include a circuit unit and a light emitting unit. The circuit unit may at least include a pixel drive circuit connected to a scan signal line, a light emitting signal line and a data signal line respectively. The light emitting unit may include a light emitting device connected to the pixel drive circuit of the circuit unit. In an exemplary implementation mode, the timing controller may provide a grayscale value and a control signal suitable for a specification of the data signal driver to the data signal driver, may provide a clock signal, a scan start signal, etc. suitable for a specification of the scan driver to the scan driver, and may provide a clock signal, an emission stop signal, etc. suitable for a specification of the light emitting driver to the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signal to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate the scan signal in a manner in which a scan start signal provided in a form of an on-level pulse is transmitted to a next-stage circuit sequentially under control of the clock signal, wherein m may be a natural number. The light emitting driver may receive the clock signal, the emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate the emission signal in a manner in which an emission stop signal provided in a form of an off-level pulse is transmitted to a next-stage circuit sequentially under control of the clock signal, wherein o may be a natural number. In an exemplary implementation mode, the pixel array may be disposed on a display substrate.

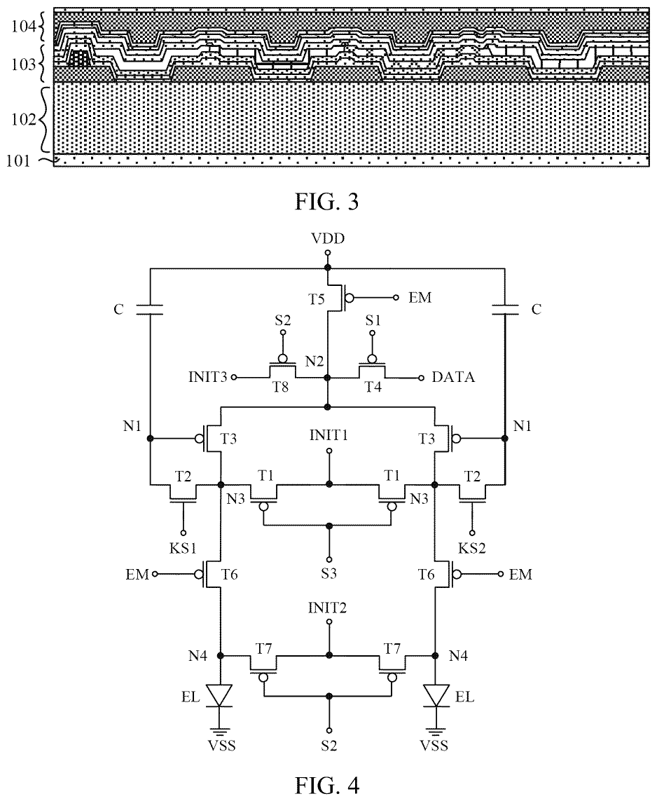

FIG. 2 is a schematic diagram of a planar structure of a display substrate. As shown in FIG. 2, the display substrate may include a plurality of pixel units P arranged in a matrix, and at least one of the pixel units P may include a first sub-pixel P1, a second sub-pixel P2, a third sub-pixel P3, and a fourth sub-pixel P4. Each sub-pixel may include a circuit unit and a light emitting unit. The circuit unit may at least include a pixel drive circuit, the pixel drive circuit is connected to a scan signal line, a data signal line, and a light emitting signal line respectively, and is configured to receive a data voltage transmitted by the data signal line and output a corresponding current to the light emitting unit under control of the scan signal line and the light emitting signal line. The light emitting unit may include a light emitting device connected to a pixel drive circuit of a sub-pixel where the light emitting device is located, and the light emitting device is configured to emit light of a corresponding brightness in response to the current output by the pixel drive circuit of the sub-pixel where the light emitting device is located.

In an exemplary implementation mode, the first sub-pixels P1 may be red sub-pixels (R) emitting red light, the second sub-pixels P2 and the fourth sub-pixels P4 may be green sub-pixels (G) emitting green light, and the third sub-pixels P3 may be blue sub-pixels (B) emitting blue light. In an exemplary implementation mode, a shape of a sub-pixel may be a rectangle, a diamond, a pentagon, or a hexagon. The four sub-pixels may be arranged in a diamond-shaped form to form an RGBG pixel arrangement. In other exemplary implementations, the four sub-pixels may be arranged side by side horizontally, side by side vertically, or in a manner to form a square, which is not limited in the present disclosure.

In an exemplary implementation mode, a pixel unit may include three sub-pixels, and the three sub-pixels may be arranged side by side horizontally, side by side vertically, or in a delta-shaped arrangement, which is not limited here in the present disclosure.

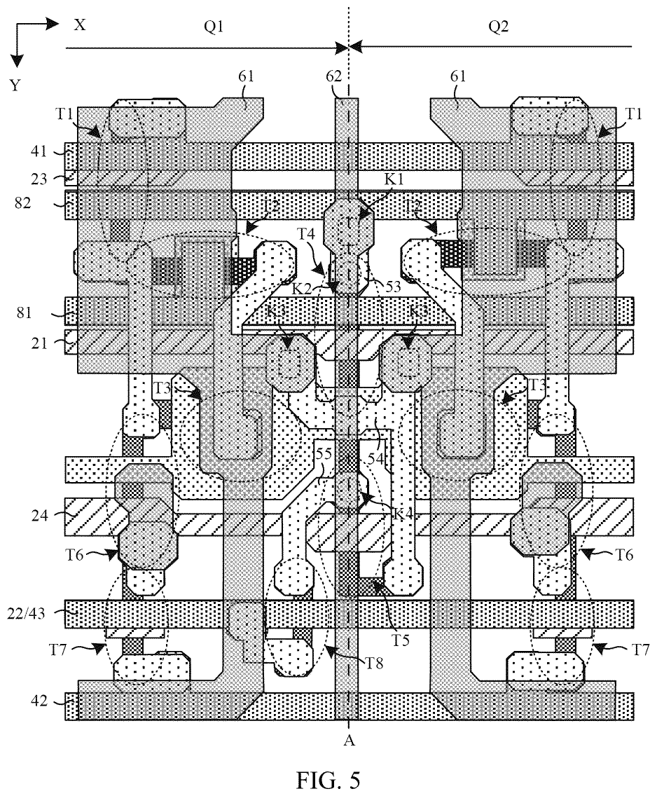

FIG. 3 is a schematic diagram of a sectional structure of a display substrate, illustrating a structure of four sub-pixels in a display region. As shown in FIG. 3, on a plane perpendicular to the display substrate, the display substrate may include a drive circuit layer 102 disposed on a base substrate 101, a light emitting structure layer 103 arranged at a side of the drive circuit layer 102 away from the base substrate 101, and an encapsulation structure layer 104 arranged at a side of the light emitting structure layer 103 away from the base substrate 101. In some possible implementation modes, the display substrate may include another film layer, such as a touch structure layer, which is not limited here in the present disclosure.

In an exemplary implementation mode, the base substrate 101 may be a flexible base substrate, or may be a rigid base substrate. The drive circuit layer 102 may include a plurality of circuit units, each of which may at least include a pixel drive circuit composed of a plurality of transistors and a storage capacitor. The light emitting structure layer 103 may include a plurality of light emitting units, and each light emitting unit may include a light emitting device. The light emitting device may at least include an anode, an organic emitting layer, and a cathode. The anode is connected to the pixel drive circuit. The organic emitting layer is connected to the anode. The cathode is connected to the organic emitting layer. The organic emitting layer emits light of a corresponding color under driving of the anode and the cathode. The encapsulation layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is arranged between the first encapsulation layer and the third encapsulation layer to form a laminated structure of inorganic material/organic material/inorganic material and ensure that external moisture cannot enter the light emitting structure layer 103.

An exemplary implementation of the present disclosure provides a display substrate. In an exemplary implementation mode, on a plane perpendicular to the display substrate, the display substrate may include a drive structure layer disposed on a base substrate and a light emitting structure layer disposed on a side of the drive structure layer away from the base substrate. On a plane parallel to the display substrate, the drive structure layer may include a plurality of circuit units constituting a plurality of unit rows and a plurality of unit columns, and at least one of the circuit units may include a pixel drive circuit configured to output a corresponding current to a light emitting device connected to the pixel drive circuit. The light emitting structure layer may include a plurality of light emitting units, at least one of the light emitting units may include a light emitting device connected to a pixel drive circuit of the corresponding circuit unit. The light emitting device is configured to emit light of a corresponding brightness in response to a current output by the pixel drive circuit connected to the light emitting device.

In an exemplary implementation mode, the circuit units mentioned in the present disclosure refer to regions divided according to pixel drive circuits, and light emitting units mentioned in the present disclosure refer to regions divided according to light emitting devices. In an exemplary implementation mode, a position and a shape of an orthographic projection of a light emitting unit on the base substrate may correspond to a position and shape of an orthographic projection of a circuit unit on the base substrate, or the position and shape of the orthographic projection of the light emitting unit on the base substrate may not correspond to the position and shape of the orthographic projection of the circuit unit on the base substrate.

In an exemplary implementation mode, the display substrate of the present disclosure may include a plurality of circuit units constituting a plurality of unit rows and a plurality of unit columns. At least one of the circuit units at least includes a pixel drive circuit. At least one pixel drive circuit at least includes a data writing transistor connected to a data signal line. The plurality of circuit units at least include a first circuit unit and a second circuit unit adjacent in a unit row direction. The first circuit unit includes a first pixel drive circuit, the second circuit unit includes a second pixel drive circuit, and the first pixel drive circuit and the second pixel drive circuit share a same data writing transistor and are connected to a same data signal line. The data signal line provides a first data signal to the first pixel drive circuit and provides a second data signal to the second pixel drive circuit sequentially through the data writing transistor.

In an exemplary implementation mode, the display substrate further includes a first control signal line and a second control signal line. The first control signal line is connected to the first pixel drive circuit, and the first control signal line is configured to enable the data signal line to provide the first data signal to the first pixel drive circuit. The second control signal line is connected to the second pixel drive circuit, and the second control signal line is configured to enable the data signal line to provide a second data signal to the second pixel drive circuit.

In an exemplary implementation mode, the pixel drive circuit further includes a light emitting control transistor, and the first pixel drive circuit and the second pixel drive circuit share a same light emitting control transistor. A first electrode of the light emitting control transistor is connected to the first power supply line, and a second electrode of the light emitting control transistor is connected to a second electrode of the data writing transistor.

In an exemplary implementation mode, the pixel drive circuit further includes an initialization transistor, and the first pixel drive circuit and the second pixel drive circuit share a same initialization transistor. A first electrode of the initialization transistor is connected to an initial signal line, and a second electrode of the initialization transistor is connected to the second electrode of the data writing transistor.

A display substrate according to an exemplary embodiment of the present disclosure is illustrated below by some examples.

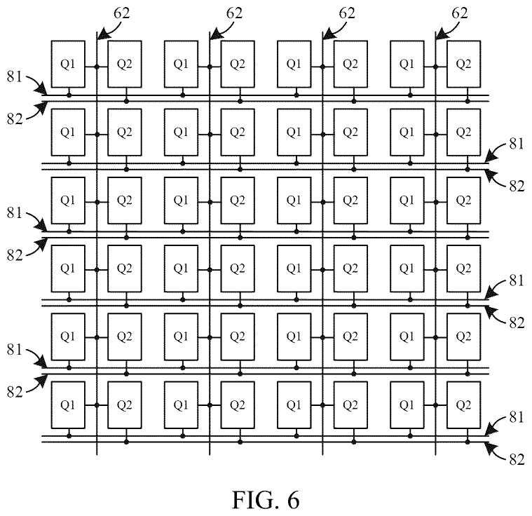

FIG. 4 is an equivalent circuit diagram of a pixel drive circuit according to an exemplary embodiment of the present disclosure, illustrating structures of a first pixel drive circuit (left side) in a first circuit unit and a second pixel drive circuit (right side) in a second circuit unit. As shown in FIG. 4, the pixel drive circuit in each circuit unit may include eight transistors (a first transistor T1 to an eighth transistor T8) and one storage capacitor C, and each pixel drive circuit is connected to 10 signal lines (a first scan signal line S1, a second scan signal line S2, a third scan signal line S3, a control signal line KS, a light emitting signal line EM, a first initial signal line IN1T1, a second initial signal line IN1T2, a third initial signal line IN1T3, a data signal line DATA and a first power supply line VDD) respectively.

In an exemplary implementation mode, each pixel drive circuit may include a first node N1, a second node N2, a third node N3 and a fourth node N4. The first node N1 is respectively connected to a first electrode of the second transistor T2, a gate electrode of the third transistor T3 and a first end of the storage capacitor C. The second node N2 is respectively connected to a first electrode of the third transistor T3, a second electrode of the fourth transistor T4, a second electrode of the fifth transistor T5 and a second electrode of the eighth transistor T8. The third node N3 is respectively connected to a second electrode of the first transistor T1, a second electrode of the second transistor T2, a second electrode of the third transistor T3 and a first electrode of the sixth transistor T6. The fourth node N4 is respectively connected to a second electrode of the sixth transistor T6 and a second electrode of the seventh transistor T7, and the fourth node N4 is also connected to an anode of a light emitting device EL.

In an exemplary implementation mode, a first end of the storage capacitor C in each pixel drive circuit is connected to the first node N1, and a second end of the storage capacitor C is connected to the first power supply line VDD.

In an exemplary implementation mode, the first transistors T1 in the first pixel drive circuit and the second pixel drive circuit may be referred to as first initialization transistors. A gate electrode of each first transistor T1 is connected to the third scan signal line S3, a first electrode of each first transistor T1 is connected to the first initial signal line IN1T1, and a second electrode of each first transistor T1 is connected to the third node N3. In an exemplary implementation mode, gate electrodes of the first transistors T1 in the first pixel drive circuit and the second pixel drive circuit may be connected to each other, and the first electrodes of the first transistors T1 in the first pixel drive circuit and the second pixel drive circuit may be connected to each other.

In an exemplary implementation mode, the second transistor T2 in each pixel drive circuit may be referred to as a compensation transistor, a first electrode of the second transistor T2 is connected to the first node N1, and a second electrode of the second transistor T2 is connected to the third node N3. A gate electrode of the second transistor T2 in the first pixel drive circuit is connected to the first control signal line KS1, and a gate electrode of the second transistor T2 in the second pixel drive circuit is connected to the second control signal line KS2.

In an exemplary implementation mode, third transistors T3 in the first pixel drive circuit and the second pixel drive circuit may be referred to as drive transistors, a gate electrode of each third transistor T3 is connected to the first node N1, i.e, the gate electrode of the third transistor T3 is connected to the first end of the storage capacitor C, a first electrode of each third transistor T3 is connected to the second node N2, and a second electrode of each third transistor T3 is connected to the third node N3. In an exemplary implementation mode, second electrodes of the third transistors T3 in the first pixel drive circuit and the second pixel drive circuit may be connected to each other.

In an exemplary implementation mode, fourth transistors T4 in the first pixel drive circuit and the second pixel drive circuit may be referred to as data writing transistors, a gate electrode of each fourth transistor T4 is connected to the first scan signal line S1, a first electrode of each fourth transistor T4 is connected to the data signal line DATA, and a second electrode of each fourth transistor T4 is connected to the second node N2. In an exemplary implementation mode, the fourth transistor T4 in the first pixel drive circuit may serve as the fourth transistor T4 in the second pixel drive circuit, or the fourth transistor T4 in the second pixel drive circuit may serve as the fourth transistor T4 in the first pixel drive circuit, that is, the first pixel drive circuit and the second pixel drive circuit share the same fourth transistor T4.

In an exemplary implementation mode, fifth transistors T5 in the first pixel drive circuit and the second pixel drive circuit may be referred to as first light emitting control transistors, a gate electrode of each fifth transistor T5 is connected to the light emitting signal line EM, a first electrode of each fifth transistor T5 is connected to the first power supply line VDD, and a second electrode of each fifth transistor T5 is connected to the second node N2. In an exemplary implementation mode, the fifth transistor T5 in the first pixel drive circuit may serve as the fifth transistor T5 in the second pixel drive circuit, or the fifth transistor T5 in the second pixel drive circuit may serve as the fifth transistor T5 in the first pixel drive circuit, that is, the first pixel drive circuit and the second pixel drive circuit share the same fifth transistor T5.

In an exemplary implementation mode, the sixth transistor T6 in each pixel drive circuit may be referred to as a second light emitting control transistor, a gate electrode of the sixth transistor T6 is connected to the light emitting signal line EM, a first electrode of the sixth transistor T6 is connected to the third node N3, and a second electrode of the sixth transistor T6 is connected to the fourth node N4.

In an exemplary implementation mode, seventh transistors T7 in the first pixel drive circuit and the second pixel drive circuit may be referred to as second initialization transistors, a gate electrode of each seventh transistor T7 is connected to the second scan signal line S2, a first electrode of each seventh transistor T7 is connected to the second initial signal line IN1T2, and a second electrode of each seventh transistor T7 is connected to the fourth node N4. In an exemplary implementation mode, the gate electrodes of the seventh transistors T7 in the first pixel drive circuit and the second pixel drive circuit may be connected to each other, and the first electrodes of the seventh transistors T7 in the first pixel drive circuit and the second pixel drive circuit may be connected to each other.

In an exemplary implementation mode, eighth transistors T8 in the first pixel drive circuit and the second pixel drive circuit may be referred to as third initialization transistors, a gate electrode of each eighth transistor T8 is connected to the second scan signal line S2, a first electrode of each eighth transistor T8 is connected to the third initial signal line IN1T3, and a second electrode of each eighth transistor T8 is connected to the second node N2. In an exemplary implementation mode, the eighth transistor T8 in the first pixel drive circuit may serve as the eighth transistor T8 in the second pixel drive circuit, or the eighth transistor T8 in the second pixel drive circuit may serve as the eighth transistor T8 in the first pixel drive circuit, that is, the first pixel drive circuit and the second pixel drive circuit share the same eighth transistor T8.

In an exemplary implementation mode, the light emitting device EL in each circuit unit may be an OLED including an anode (first electrode), an organic emitting layer, and a cathode (second electrode) that are stacked, or may be a QLED including an anode (first electrode), a quantum dot emitting layer, and a cathode (second electrode) that are stacked.

In an exemplary implementation mode, a first electrode of the light emitting device EL in each circuit unit is connected to the fourth node N4, and a second electrode of the light emitting device EL is connected to a second power supply line VSS.

In an exemplary implementation mode, a signal of the first power supply line VDD is a high-level signal continuously provided, and a signal of the second power supply line VSS is a low-level signal continuously provided.

In some possible exemplary implementation modes, the first to eighth transistors T1 to T8 in each pixel drive circuit may be P-type transistors or may be N-type transistors. In some other possible exemplary implementation modes, the first to eighth transistors T1 to T8 in each pixel drive circuit may include P-type transistors and N-type transistors.

In an exemplary implementation mode, the first transistor T1 to the eighth transistor T8 in each pixel drive circuit may be low temperature polysilicon transistors, or may be oxide transistors, or may be a low temperature polysilicon transistor(s) and a metal oxide transistor(s). Low Temperature Poly-Silicon (LTPS for short) is used for an active layer of a low temperature polysilicon transistor and a metal oxide semiconductor (Oxide) is used for an active layer of a metal oxide transistor. The low temperature polysilicon transistor has advantages such as a high migration rate and fast charging, and the oxide transistor has advantages such as a low drain current. The low temperature polysilicon transistor and the metal oxide transistor are integrated on one display substrate to form a Low Temperature Polycrystalline Oxide (LTPO for short) display substrate, such that advantages of the low temperature polysilicon transistor and the metal oxide transistor may be utilized, low-frequency drive may be achieved, power consumption may be reduced, and display quality may be improved.

In an exemplary implementation mode, the second transistors T2 in the first pixel drive circuit and the second pixel drive circuit may be metal oxide transistors (N-type transistors), and the first transistor T1, the third transistor T3 to the eighth transistor T8 may be low temperature polysilicon transistors (P-type transistors).

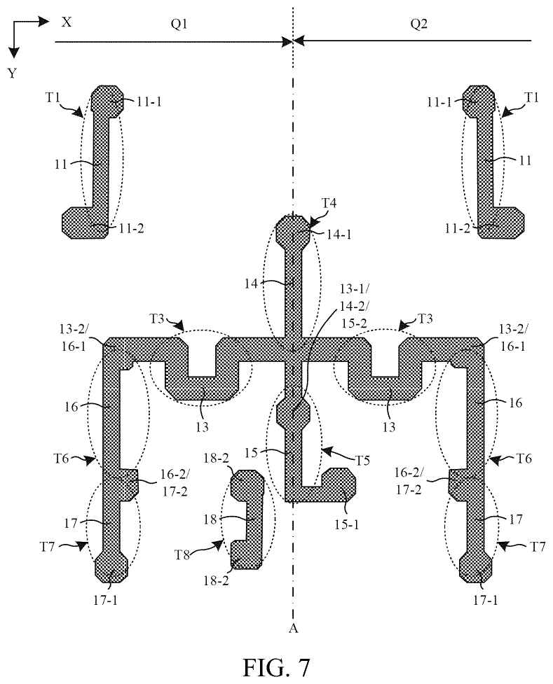

FIG. 5 is a schematic diagram of a planar structure of a display substrate according to an exemplary embodiment of the present disclosure, illustrating structures of a first circuit unit Q1 and a second circuit unit Q2 adjacent in a first direction X (a unit row direction). In an exemplary implementation mode, the display substrate may include a plurality of circuit units, the plurality of circuit units may form a plurality of unit rows and a plurality of unit columns, the plurality of circuit units in each unit row are sequentially arranged along the first direction X, and the plurality of unit rows are sequentially arranged along a second direction Y, constituting a circuit unit array arranged in an array, and the first direction X and the second direction Y intersect.

As shown in FIG. 5, the first circuit unit Q1 may include a first pixel drive circuit, the second circuit unit Q2 may include a second pixel drive circuit, and each pixel drive circuit may at least include a storage capacitor and a plurality of transistors. The storage capacitor may include a first plate and a second plate which are stacked, and the plurality of transistors may include a first transistor T1, a second transistor T2, a third transistor T3, a fourth transistor T4, a fifth transistor T5, a sixth transistor T6, a seventh transistor T7, and an eighth transistor T8. The second transistor T2 is an oxide transistor, and the first transistor T1, the third transistor T3 to the eighth transistor T8 are low temperature polysilicon transistors.

In an exemplary implementation mode, the fourth transistor T4 in the first pixel drive circuit may serve as the fourth transistor T4 in the second pixel drive circuit, or the fourth transistor T4 in the second pixel drive circuit may serve as the fourth transistor T4 in the first pixel drive circuit, the first pixel drive circuit and the second pixel drive circuit share the same fourth transistor T4, and the fourth transistor T4 may serve as a data writing transistor in the present disclosure.

In an exemplary implementation mode, the fifth transistor T5 in the first pixel drive circuit may serve as the fifth transistor T5 in the second pixel drive circuit, or the fifth transistor T5 in the second pixel drive circuit may serve as the fifth transistor T5 in the first pixel drive circuit, the first pixel drive circuit and the second pixel drive circuit share a same fifth transistor T5, and the fifth transistor T5 may serve as a light emitting control transistor in the present disclosure.

In an exemplary implementation mode, the eighth transistor T8 in the first pixel drive circuit may serve as the eighth transistor T8 in the second pixel drive circuit, or the eighth transistor T8 in the second pixel drive circuit may serve as the eighth transistor T8 in the first pixel drive circuit, the first pixel drive circuit and the second pixel drive circuit share a same eighth transistor T8, and the eighth transistor T8 may serve as an initialization transistor in the present disclosure.

In an exemplary implementation mode, in each pixel drive circuit, a gate electrode of the first transistor T1 is connected to a third scan signal line 23, a first electrode of the first transistor T1 is connected to a first initial signal line 41, and a second electrode of the first transistor T1 is connected to the second electrode of the third transistor T3.

In an exemplary implementation mode, the second transistor T2 in the first pixel drive circuit may serve as a first compensation transistor, and the third transistor T3 in the first pixel drive circuit may serve as a first drive transistor. In the first pixel drive circuit, the second transistor T2 is connected to a first control signal line 81, a first electrode of the second transistor T2 is connected to a gate electrode of the third transistor T3, and a second electrode of the second transistor T2 is connected to a second electrode of the third transistor T3.

In an exemplary implementation mode, the second transistor T2 in the second pixel drive circuit may serve as a second compensation transistor, and the third transistor T3 in the second pixel drive circuit may serve as a second drive transistor. In the second pixel drive circuit, the second transistor T2 is connected to a second control signal line 82, a first electrode of the second transistor T2 is connected to a gate electrode of the third transistor T3, and a second electrode of the second transistor T2 is connected to a second electrode of the third transistor T3.

In an exemplary implementation mode, the fourth transistor T4 shared by the first pixel drive circuit and the second pixel drive circuit may serve as a data writing transistor. A gate electrode of the fourth transistor T4 is connected to a first scan signal line 21, a first electrode of the fourth transistor T4 is connected to a data signal line 62, and a second electrode of the fourth transistor T4 is connected to first electrodes of the third transistors T3 in the two pixel drive circuits.

In an exemplary implementation mode, the fifth transistor T5 shared by the first pixel drive circuit and the second pixel drive circuit may serve as a first light emitting control transistor. A gate electrode of the fifth transistor T5 is connected to a light emitting signal line 24, a first electrode of the fifth transistor T5 is connected to a first power supply line 61, and a second electrode of the fifth transistor T5 is simultaneously connected to the first electrodes of the third transistors T3 of the two pixel drive circuits and the second electrode of the fourth transistor T4 shared by the two pixel drive circuits.

In an exemplary implementation mode, in each pixel drive circuit, a gate electrode of the sixth transistor T6 is connected to the light emitting signal line 24, a first electrode of the sixth transistor T6 is connected to the second electrode of the third transistor T3, and a second electrode of the sixth transistor T6 is connected to a second electrode of the seventh transistor T7.

In an exemplary implementation mode, in each pixel drive circuit, a gate electrode of the seventh transistor T7 is connected to a second scan signal line 22, a first electrode of the seventh transistor T7 is connected to a second initial signal line 42, and a second electrode of the seventh transistor T7 is connected to a second electrode of the sixth transistor T6.

In an exemplary implementation mode, the eighth transistor T8 shared by the first pixel drive circuit and the second pixel drive circuit may serve as an initialization transistor. A gate electrode of the eighth transistor T8 is connected to the second scan signal line 22, a first electrode of the eighth transistor T8 is connected to a third initial signal line 43, and a second electrode of the eighth transistor T8 is simultaneously connected to the first electrodes of the third transistors T3 of the two pixel drive circuits, the second electrode of the fourth transistor T4 shared by the two pixel drive circuits, and the second electrode of the fifth transistor T5 shared by the two pixel drive circuits.

In an exemplary implementation mode, the first scan signal line 21, the second scan signal line 22, the third scan signal line 23, the light emitting signal line 24, the first initial signal line 41, the second initial signal line 42, the third initial signal line 43, the first control signal line 81 and the second control signal line 82 may each be in a shape of a straight line or a bending line whose main portion extends in the first direction X, and the first power supply line 61 and the data signal line 62 may each be in a shape of a straight line or a bending line whose main portion extends in the second direction Y.

In the present disclosure, “A extends along a B direction” means that A may include a main portion and a secondary portion connected to the main portion, the main portion is a line, a line segment, or a strip-shaped body, the main portion extends along the B direction, and a length of the main portion extending along the B direction is greater than a length of the secondary portion extending along another direction. In following description, “A extends in a B direction” means “a main portion of A extends in a B direction”.

In an exemplary implementation mode, a data signal line 62 to which the first pixel drive circuit is connected may serve as a data signal line 62 to which the second pixel drive circuit is connected, or the data signal line 62 to which the second pixel drive circuit is connected may serve as the data signal line 62 to which the first pixel drive circuit is connected, the first pixel drive circuit and the second pixel drive circuit are connected to a same data signal line 62, i.e. the first pixel drive circuit and the second pixel drive circuit share the same data signal line 62.

In an exemplary implementation mode, the data signal line 62 may sequentially provide a first data signal to the first pixel drive circuit and provide a second data signal to the second pixel drive circuit through the fourth transistor T4, that is, in one period of time, the data signal line 62 provides the first data signal required by the first pixel drive circuit to the first pixel drive circuit, and in another period of time, the data signal line 62 provides the second data signal required by the second pixel drive circuit to the second pixel drive circuit.

In an exemplary implementation mode, the data signal line 62 shared by the first pixel drive circuit and the second pixel drive circuit may be provided at a position between the first circuit unit Q1 and the second circuit unit Q2, and an orthographic projection of the data signal line 62 on a plane of the display substrate at least partially overlaps with an orthographic projection of a unit dividing line A on the plane of the display substrate. The unit dividing line A is a straight line located between the first circuit unit Q1 and the second circuit unit Q2 and extending along the second direction Y.

In an exemplary implementation mode, the fourth transistor T4 shared by the first pixel drive circuit and the second pixel drive circuit may be disposed at a position between the first circuit unit Q1 and the second circuit unit Q2, an orthographic projection of the fourth transistor T4 on the plane of the display substrate at least partially overlaps with the orthographic projection of the unit dividing line A on the plane of the display substrate.

In an exemplary implementation mode, the fourth transistor T4 may at least include a fourth active layer, and the data signal line 62 may be connected to a first region of the fourth active layer through a third connection electrode 53. An orthographic projection of the fourth active layer on the plane of the display substrate at least partially overlaps with the orthographic projection of the unit dividing line A on the plane of the display substrate, and an orthographic projection of the third connection electrode 53 on the plane of the display substrate at least partially overlaps with the orthographic projection of the unit dividing line A on the plane of the display substrate. The fourth active layer may serve as a data writing active layer in the present disclosure and the third connection electrode 53 may serve as a data connection in of the present disclosure.

In an exemplary implementation mode, in a direction perpendicular to the display substrate, the display substrate may include a plurality of conductive layers arranged sequentially on the base substrate. The data signal line 62 and the third connection electrode 53 may be arranged in different conductive layers, the data signal line 62 is connected to the third connection electrode 53 through a first connection via K1. An orthographic projection of the first connection via K1 on the plane of the display substrate at least partially overlaps with the orthographic projection of the unit dividing line A on the plane of the display substrate.

In an exemplary implementation mode, in the direction perpendicular to the display substrate, the display substrate may further include a first semiconductor layer, the fourth active layer may be disposed in the first semiconductor layer, and the third connection electrode 53 is connected to the first region of the fourth active layer through a second connection via K2. An orthographic projection of the second connection via K2 on the plane of the display substrate at least partially overlaps with the orthographic projection of the unit dividing line A on the plane of the display substrate.

In an exemplary implementation mode, the fifth transistor T5 shared by the first pixel drive circuit and the second pixel drive circuit may be provided in a region between the first circuit unit Q1 and the second circuit unit Q2, and an orthographic projection of the fifth transistor T5 on the plane of the display substrate at least partially overlaps with the orthographic projection of the unit dividing line A on the plane of the display substrate.

In an exemplary implementation mode, the fifth transistor T5 may at least include a fifth active layer, and the first power supply line 61 may be connected to a first region of the fifth active layer through a fourth connection electrode 54. An orthographic projection of the fifth active layer on the plane of the display substrate at least partially overlaps with the orthographic projection of the unit dividing line A on the plane of the display substrate, and an orthographic projection of the fourth connection electrode 54 on the plane of the display substrate at least partially overlaps with the orthographic projection of the unit dividing line A on the plane of the display substrate. The fifth active layer may serve as a light emitting control active layer in the present disclosure and the fourth connection electrode 54 may serve as a power supply connection electrode in the present disclosure.

In an exemplary implementation mode, the first power supply line 61 and the fourth connection electrode 54 may be provided in different conductive layers, and the first power supply line 61 is connected to the fourth connection electrode 54 through a third connection via K3, and third connection vias K3 may be provided in the first circuit unit Q1 and the second circuit unit Q2, respectively.

In an exemplary implementation mode, the eighth transistor T8 shared by the first pixel drive circuit and the second pixel drive circuit may be provided in the first circuit unit Q1 or may be provided in the second circuit unit Q2.

In an exemplary implementation mode, the eighth transistor T8 may at least include an eighth active layer, a first region of the eighth active layer is connected to the third initial signal line 43, and a second region of the eighth active layer is connected to a second region of the fourth active layer through a fifth connection electrode 55. An orthographic projection of the eighth active layer on the plane of the display substrate does not overlap with the orthographic projection of the unit dividing line A on the plane of the display substrate, and an orthographic projection of the fifth connection electrode 55 on the plane of the display substrate at least partially overlaps with the orthographic projection of the unit dividing line A on the plane of the display substrate. The eighth active layer may serve as an initialization active layer in the present disclosure and the fifth connection electrode 55 may serve as an initial connection electrode in the present disclosure.

In an exemplary implementation mode, the eighth active layer may be disposed in the first semiconductor layer, and the fifth connection electrode 55 is connected to the second region of the fourth active layer through a fourth connection via K4. An orthographic projection of the fourth connection via K4 on the plane of the display substrate at least partially overlaps with the orthographic projection of the unit dividing line A on the plane of the display substrate.

In an exemplary implementation mode, in the direction perpendicular to the display substrate, the display substrate may include a plurality of conductive layers sequentially disposed on the base substrate. The first initial signal line 41, the second initial signal line 42, and the third initial signal line 43 may be disposed in a same conductive layer, the first power supply line 61 and the data signal line 62 may be disposed in a same conductive layer, and the first control signal line 81 and the second control signal line 82 may be disposed in a same conductive layer.

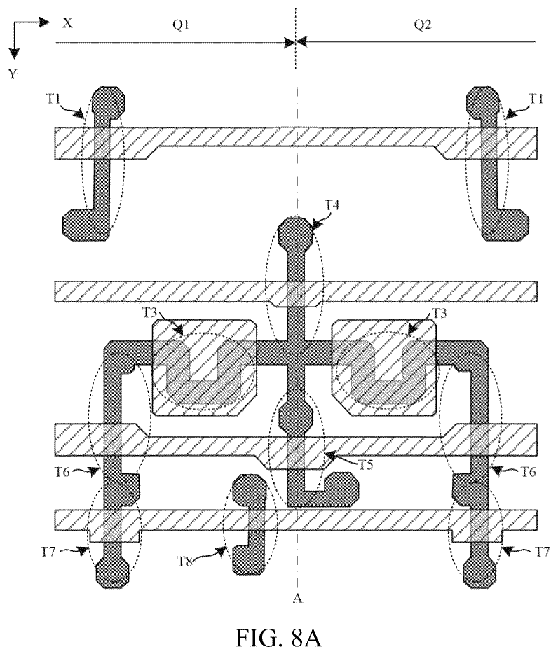

FIG. 6 is a schematic diagram of connection between pixel drive circuits and signal lines according to an exemplary embodiment of the present disclosure. As shown in FIG. 6, the display substrate includes a plurality of unit rows and a plurality of unit columns, first circuit units Q1 and second circuit units Q2 in each unit row are alternately arranged along the first direction X. The plurality of unit rows are sequentially arranged along the second direction Y, and each unit column includes a plurality of first circuit units Q1 or includes a plurality of second circuit units Q2. Each first circuit unit Q1 includes a first pixel drive circuit, and each second circuit unit Q2 includes a second pixel drive circuit.

In an exemplary implementation mode, each unit row further includes a first control signal line 81 and a second control signal line 82. The first control signal line 81 in each unit row is connected to a plurality of first pixel drive circuits in the present unit row and the second control signal line 82 in each unit row is connected to a plurality of second pixel drive circuits in the present unit row.

In an exemplary implementation mode, a data signal line 62 is further included in every two unit columns, and the data signal line 62 is connected to a plurality of first pixel drive circuits and a plurality of second pixel drive circuits in the two unit columns respectively.

In an exemplary implementation mode, the first control signal line 81 is configured such that the data signal line 62 provides a first data signal to the first pixel drive circuits, and the second control signal line 82 is configured such that the data signal line 62 provides a second data signal to the second pixel drive circuits.

In an exemplary implementation mode, in one unit row, the first control signal line 81 is connected to gate electrodes of the second transistors T2 in the plurality of first pixel drive circuits, and the second control signal line 82 is connected to gate electrodes of the second transistors T2 in the plurality of second pixel drive circuits.

Exemplary description is made below through a manufacturing process of a display substrate. A “patterning process” mentioned in the present disclosure includes a treatment such as deposition of a film layer, photoresist coating on a film layer, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through a patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same one-time patterning process, and a “thickness” of a film layer is a dimension of the film layer in a direction perpendicular to the display substrate. In an exemplary embodiment of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

In an exemplary implementation mode, taking two circuit units (the first circuit unit Q1 and the second circuit unit Q2) as an example, a manufacturing process of the display substrate according to this embodiment may include the following operations.

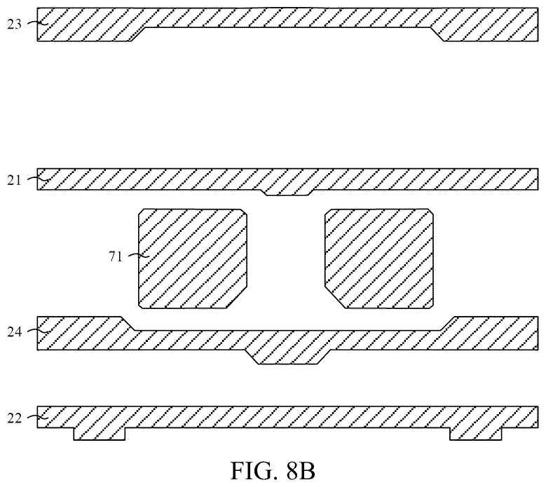

(1) Forming a pattern of a first semiconductor layer. In an exemplary implementation mode, forming the pattern of the first semiconductor layer may include: depositing a first insulation thin film and a first semiconductor thin film sequentially on a base substrate, and patterning the first semiconductor thin film through a patterning process to form a first insulation layer covering the base substrate and the pattern of the first semiconductor layer disposed on the first insulation layer, as shown in FIG. 7.

In an exemplary implementation mode, the pattern of the first semiconductor layer of each circuit unit may at least include a first active layer 11 of the first transistor T1, a third active layer 13 of the third transistor T3 to an eighth active layer 18 of the eighth transistor T8, and the third active layer 13 to the seventh active layer 17 of each circuit unit are interconnected to form an integral structure, and the first active layer 11 and the eighth active layer 18 are individually provided.

In an exemplary implementation mode, in the first direction X, the first active layer 11, the sixth active layer 16 and the seventh active layer 17 of each circuit unit may be located at a side of the third active layer 13 away from the unit dividing line A in the present circuit unit, and the fourth active layer 14 and the fifth active layer 15 may be located between the first circuit unit Q1 and the second circuit unit Q2. An orthographic projection of the fourth active layer 14 on the base substrate at least partially overlaps with the orthographic projection of the unit dividing line A on the base substrate, and an orthographic projection of the fifth active layer 15 on the base substrate at least partially overlaps with the orthographic projection of the unit dividing line A on the base substrate.

In an exemplary implementation mode, in the second direction Y, the first active layer 11 and the fourth active layer 14 of each circuit unit may be located on a side of the third active layer 13 in the present circuit unit in an opposite direction of the second direction Y, and the fifth active layer 15, the sixth active layer 16, the seventh active layer 17 and the eighth active layer 18 may be located on a side of the third active layer 13 in the present circuit unit in the second direction Y.

In an exemplary implementation mode, the third active layer 13 of each circuit unit may be in a shape of an inverted “Ω”, the first active layer 11, the fourth active layer 14, the sixth active layer 16, the seventh active layer 17, and the eighth active layer 18 may each be in a shape of an “I”, and the fifth active layer 15 may be in a shape of an “L”.

In an exemplary implementation mode, the first active layer 11, the third active layer 13 to the eighth active layer 18 of each circuit unit may each include a first region, a second region, and a channel region located between the first region and the second region. In an exemplary implementation mode, the first region 13-1 of the third active layer may simultaneously serve as the second region 14-2 of the fourth active layer and the second region 15-2 of the fifth active layer. The second region 13-2 of the third active layer may serve as the first region 16-1 of the sixth active layer. The second region 16-2 of the sixth active layer may serve as the second region 17-2 of the seventh active layer. The first region 11-1 of the first active layer, the second region 11-2 of the first active layer, the first region 14-1 of the fourth active layer, the first region 15-1 of the fifth active layer, the first region 17-1 of the seventh active layer, the first region 18-1 of the eighth active layer and the second region 18-2 of the eighth active layer may be individually provided.

In an exemplary implementation mode, the first region 14-1 of the fourth active layer, the second region 14-2 of the fourth active layer and the second region 15-2 of the fifth active layer may be located between the first circuit unit Q1 and the second circuit unit Q2. Orthographic projections of the first region 14-1 of the fourth active layer, the second region 14-2 of the fourth active layer and the second region 15-2 of the fifth active layer on the base substrate at least partially overlaps with the orthographic projection of the unit dividing line A on the base substrate. The first region 15-1 of the fifth active layer may be located at a position in the second circuit unit Q2 close to the unit dividing line A, and the first region 18-1 of the eighth active layer and the second region 18-2 of the eighth active layer may be located at a position in the first circuit unit Q1 close to the unit dividing line A.

In an exemplary implementation mode, the fourth active layer 14 may simultaneously serve as the fourth active layers of the first circuit unit and the second circuit unit, the fifth active layer 15 may simultaneously serve as the fifth active layers of the first circuit unit and the second circuit unit, and the eighth active layer 18 may simultaneously serve as the eighth active layers of the first circuit unit and the second circuit unit, i.e, the first circuit unit Q1 and the second circuit unit Q2 may share the fourth active layer 14, the first circuit unit Q1 and the second circuit unit Q2 may share the fifth active layer 15, and the first circuit unit Q1 and the second circuit unit Q2 may share the eighth active layer 18.

In an exemplary implementation mode, the first region 13-1 of the third active layer in the first circuit unit Q1 and the first region 13-1 of the third active layer in the second circuit unit Q2 may be connected to each other.

In an exemplary implementation mode, the third active layer 13 in the first circuit unit Q1 and the third active layer 13 in the second circuit unit may be interconnected to form an integral structure. Since the third active layer 13 to the seventh active layer 17 of each circuit unit are of an interconnected integral structure, the third active layers 13 to the seventh active layers 17 in the first circuit unit Q1 and the second circuit unit Q2 are of an interconnected integral structure.

In an exemplary implementation mode, the first semiconductor layer may be made of poly Silicon (p-Si), i.e, the first transistor and the third to eighth transistors are LTPS transistors. In an exemplary implementation mode, the patterning the first semiconductor thin film through the patterning process may include: forming an amorphous silicon (a-si) thin film on the first insulation thin film, dehydrogenating the amorphous silicon thin film, and crystallizing the dehydrogenated amorphous silicon thin film to form a poly silicon thin film. Subsequently, the poly silicon thin film is patterned to form the pattern of the first semiconductor layer.

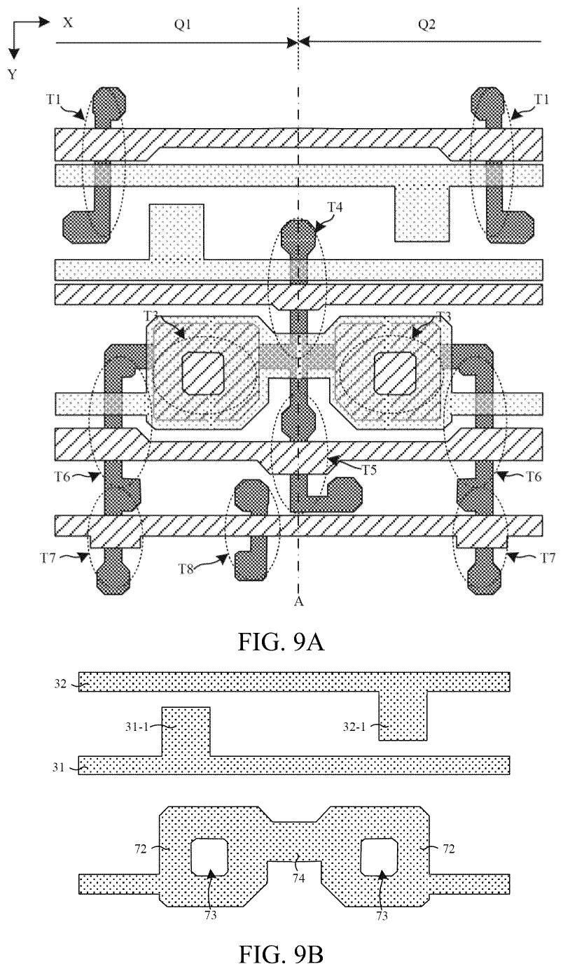

(2) A pattern of a first conductive layer is formed. In an exemplary implementation mode, forming the pattern of the first conductive layer may include: depositing sequentially a second insulation thin film and a first conductive thin film on the base substrate on which the aforementioned patterns are formed, and patterning the first conductive thin film through a patterning process to form a second insulation layer that covers the pattern of the first semiconductor layer and form the pattern of the first conductive layer disposed on the second insulation layer, as shown in FIG. 8A and FIG. 8B, and FIG. 8B is a schematic plan view of the first conductive layer in FIG. 8A. In an exemplary implementation mode, the first conductive layer may be referred to as a first gate metal (GATE1) layer.

In an exemplary implementation mode, the pattern of the first conductive layer of each circuit unit at least includes: a first scan signal line 21, a second scan signal line 22, a third scan signal line 23, a light emitting signal line 24, and a first plate 71 of a storage capacitor.

In an exemplary implementation mode, the first plate 71 in each circuit unit may be in a shape of a rectangle, and chamfers may be provided at corners of the rectangle. An orthographic projection of the first plate 71 on the base substrate is at least partially overlapped with an orthographic projection of a third active layer of a third transistor T3 on the base substrate. In an exemplary implementation mode, the first plate 71 may serve as a plate of the storage capacitor and a gate electrode of the third transistor T3 simultaneously.

In an exemplary implementation mode, the first scan signal line 21 may be in a shape of a bending line in which a main portion extends along the first direction X, the first scan signal line 21 may be located at a side of the first plate 71 in an opposite direction of the second direction Y, and a region where the first scan signal line 21 overlaps with the fourth active layer may serve as a gate electrode of the fourth transistor T4.

In an exemplary implementation mode, the second scan signal line 22 may be in a shape of a straight line or a bending line in which a main portion extends along the first direction X, the second scan signal line 22 may be located at a side of the first plate 71 in the second direction Y, a region where the second scan signal line 22 overlaps with the seventh active layer in each circuit unit may serve as a gate electrode of the seventh transistor T7, and a region where the second scan signal line 22 overlaps with the eighth active layer may serve as a gate electrode of the eighth transistor T8.

In an exemplary implementation mode, the third scan signal line 23 may be in a shape of a straight line or a bending line in which a main portion extends along the first direction X, the third scan signal line 23 may be located at a side of the first scan signal line 21 away from the first plate 71, and a region where the third scan signal line 23 overlaps with the first active layer in each circuit unit may serve as a gate electrode of the first transistor T1.

In an exemplary implementation mode, the light emitting signal line 24 may be in a shape of a straight line or a bending line in which a main portion extends along the first direction X, the light emitting signal line 24 may be located between the second scan signal line 22 and the first plate 71, a region where the light emitting signal line 24 overlaps with the fifth active layer may serve as a gate electrode of the fifth transistor T5, and a region where the light emitting signal line 24 overlaps with the sixth active layer in each circuit unit may serve as a gate electrode of the sixth transistor T6.

In an exemplary implementation mode, the first scan signal line 21, the second scan signal line 22, the third scan signal line 23, and the light emitting signal line 24 each include a region which is overlapped with the first semiconductor layer and a region which is not overlapped with the first semiconductor layer, and a width of at least one signal line in the region which is overlapped with the first semiconductor layer may be greater than a width of at least one signal line in the region which is not overlapped with the first semiconductor layer, and the width is a size in the second direction Y.

In an exemplary implementation mode, after the pattern of the first conductive layer is formed, a conductive treatment may be performed on the first semiconductor layer by using the first conductive layer as a shield. A region of the first semiconductor layer, which is shielded by the first conductive layer, forms channel regions of the first transistor T1, the third transistor T3 to the eighth transistor T8, and a region of the first semiconductor layer, which is not shielded by the first conductive layer, is made to be conductive, that is, first regions and second regions of the first transistor T1, the third transistor T3 to the eighth transistor T8 are all made to be conductive.

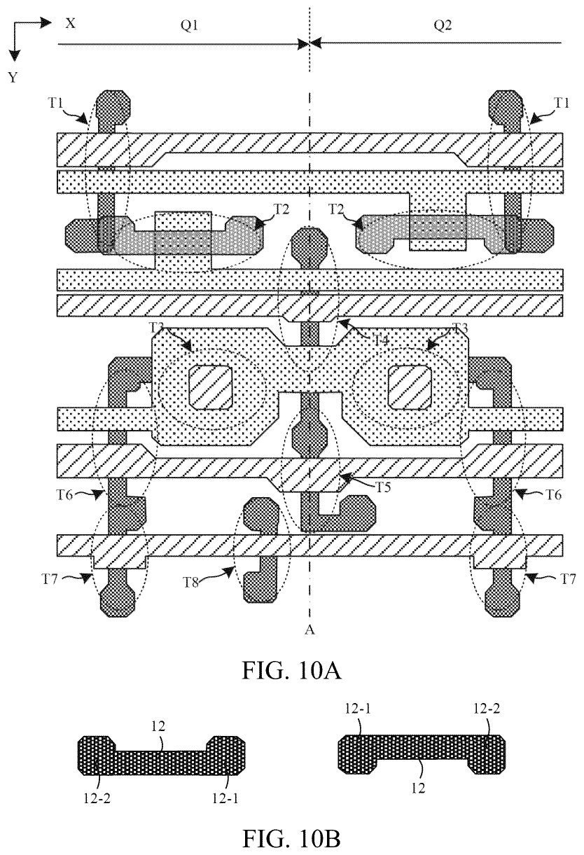

(3) A pattern of a second conductive layer is formed. In an exemplary implementation mode, forming a pattern of a second conductive layer may include: depositing sequentially a third insulation thin film and a second conductive thin film on the base substrate on which the aforementioned patterns are formed, and patterning the second conductive thin film through a patterning process to form a third insulation layer that covers the first conductive layer and the pattern of the second conductive layer disposed on the third insulation layer, as shown in FIG. 9A and FIG. 9B. FIG. 9B is a schematic plan view of the second conductive layer in FIG. 9A. In an exemplary implementation mode, the second conductive layer may be referred to as a second gate metal (GATE2) layer.

In an exemplary implementation mode, the pattern of the second conductive layer of each circuit unit at least includes a first shielding line 31, a second shielding line 32 and a second plate 72 of the storage capacitor.

In an exemplary implementation mode, the first shielding line 31 and the second shielding line 32 may each be in a shape of a straight line or a bending line whose main portion extends along the first direction X, and the first shielding line 31 and the second shielding line 32 may be located between the first scan signal line 21 and the third scan signal line 23. The first shielding line 31 may be located at a side of the second shielding line 32 close to the first scan signal line 21 and the second shielding line 32 may be located at a side of the first shielding line 31 close to the third scan signal line 23.

In an exemplary implementation mode, a first shielding block 31-1 is provided at a side of the first shielding line 31 away from the first scan signal line 21 in the first circuit unit Q1. The first shielding block 31-1 may be in a shape of a block (such as a rectangle), a first end of the first shielding block 31-1 is connected to the first shielding line 31, a second end of the first shielding block 31-1 extends in a direction away from the first scan signal line 21, the first shielding block 31-1 is configured as a shielding layer of the second transistor T2 in the first circuit unit Q1, to shield a channel region of the second transistor T2, ensure electrical performance of the second transistor T2 made of oxide, and is also configured as a bottom gate electrode of the second transistor T2 in the first circuit unit Q1.

In an exemplary implementation mode, the first shielding line 31 and the first shielding block 31-1 may be interconnected to form an integral structure.

In an exemplary implementation mode, a second shielding block 32-1 is provided at the side of the second shielding line 32 close to the first scan signal line 21 in the second circuit unit Q2. The second shielding block 32-1 may be in a shape of a block (such as a rectangle), a first end of the second shielding block 32-1 is connected to the second shielding line 32, a second end of the second shielding block 32-1 extends in a direction close to the first scan signal line 21, and the second shielding block 32-1 is configured as a shielding layer of the second transistor T2 in the second circuit unit Q2, to shield a channel region of the second transistor T2, ensure electrical performance of the second transistor T2 made of oxide transistor, and is also configured as a bottom gate electrode of the second transistor T2 in the second circuit unit Q2.

In an exemplary implementation mode, the second shielding line 32 and the second shielding block 32-1 may be interconnected to form an integral structure.

In an exemplary implementation mode, a profile of the second plate 72 may be in a shape of a rectangle, a chamfer may be provided at a corner of the rectangle. An orthographic projection of the second plate 72 on the base substrate is at least overlapped with an orthographic projection of the first plate 71 on the base substrate. The second plate 72 may serve as another plate of the storage capacitor, and the first plate 71 and the second plate 72 constitute the storage capacitor of the pixel drive circuit.

In an exemplary implementation mode, the second plate 72 is provided with an opening 73. The opening 73 may have a rectangular shape and may be located in the middle of the second plate 72, so that the second plate 72 is formed in an annular structure. The opening 73 exposes the third insulation layer covering the first plate 71, and an orthographic projection of the first plate 71 on the base substrate contains an orthographic projection of the opening 73 on the base substrate. In an exemplary implementation mode, the opening 73 is configured to accommodate a thirteenth via to be formed subsequently, and the thirteenth via is located within the opening 73 and exposes the first plate 71, so that a first connection electrode to be formed subsequently is connected to the first plate 71.

In an exemplary implementation mode, the second conductive layer of each circuit unit may further include a plate connection strip 74. The plate connection strip 74 may be in a shape of a strip extending along the first direction X, and the plate connection strip 74 may be provided on a side of the second plate 72 in the first direction X or on a side of the second plate 72 in an opposite direction of the first direction X. A first end of the plate connection strip 74 is connected to the second plate 72 in the present circuit unit, and a second end of the plate connection strip 74 is connected to the second plate 72 in a circuit unit adjacent in the first direction X, so that the second plates 72 in adjacent circuit units in one unit row are interconnected to be in an integral structure. Since the second plate 72 in each circuit unit is connected to a first power supply line to be formed subsequently, by forming an integral structure in which the second plates 72 of adjacent circuit units are connected to each other, the second plates of the integral structure can also be used as a power supply signal line, so that a plurality of second plates in a unit row can be ensured to have a same potential, which is beneficial for improving uniformity of the display substrate, avoiding poor display of the display substrate and ensuring a display effect of the display substrate.

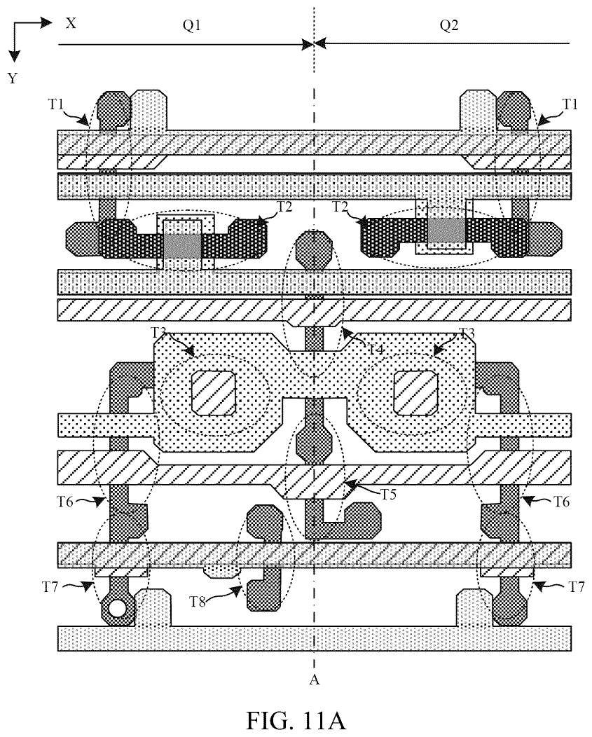

(4) Forming a pattern of a second semiconductor layer. In an exemplary implementation mode, forming the pattern of the second semiconductor layer may include: depositing a fourth insulation thin film and a second semiconductor thin film sequentially on the base substrate on which the above-mentioned patterns are formed, patterning the second semiconductor thin film through a patterning process to form a fourth insulation layer that covers the base substrate and the pattern of the second semiconductor layer disposed on the fourth insulation layer, as shown in FIG. 10A and FIG. 10B, and FIG. 10B is a schematic plan view of the second conductive layer in FIG. 10A.

In an exemplary implementation mode, the pattern of the second semiconductor layer of each circuit unit at least includes a second active layer 12 of the second transistor T2.

In an exemplary implementation mode, the second active layer 12 may be in a shape of a strip extending along the first direction X, and may be located between the first shielding line 31 and the second shielding line 32. An orthographic projection of the second active layer 12 in the first circuit unit Q1 on the base substrate at least partially overlaps with an orthographic projection of the first shielding block 31-1 on the base substrate, and an orthographic projection of the second active layer 12 in the second circuit unit Q2 on the base substrate at least partially overlaps with an orthographic projection of the second shielding block 32-1 on the base substrate.

In an exemplary implementation mode, the second active layer 12 of each circuit unit may include a first region, a second region and a channel region located between the first region and the second region. In an exemplary implementation mode, in the first circuit unit Q1, a first region 12-1 of the second active layer may be located at a side of the first shielding block 31-1 close to the fourth active layer, and a second region 12-2 of the second active layer may be located at a side of the first shielding block 31-1 away from the fourth active layer. In an exemplary implementation mode, in the second circuit unit Q2, a first region 12-1 of the second active layer may be located at a side of the second shielding block 32-1 close to the fourth active layer, and a second region 12-2 of the second active layer may be located at a side of the second shielding block 32-1 away from the fourth active layer.

In an exemplary implementation mode, the second semiconductor layer may be made of an oxide, i.e., the eighth transistor T8 is an oxide transistor. In an exemplary implementation mode, the second semiconductor thin film may be made of Indium Gallium Zinc Oxide, wherein electron mobility of the Indium Gallium Zinc Oxide (IGZO) is higher than that of amorphous silicon.

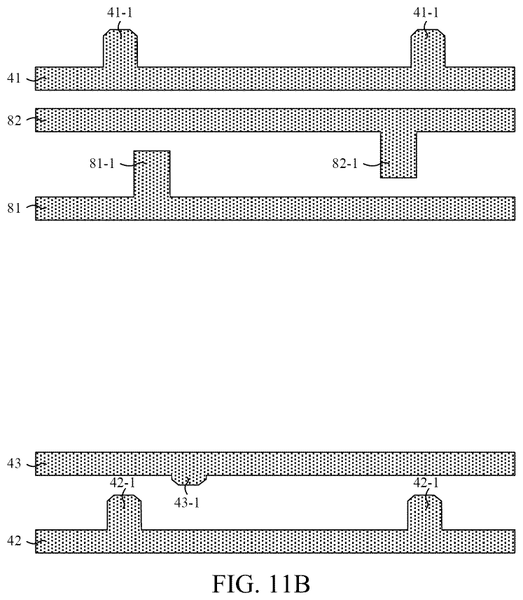

(5) Forming a pattern of a third conductive layer. In an exemplary implementation mode, forming the pattern of the third conductive layer may include: depositing a fifth insulation thin film and a third conductive thin film sequentially on the base substrate on which the aforementioned patterns are formed, and patterning the third conductive thin film through a patterning process to form a fifth insulation layer covering the second semiconductor layer and the pattern of the third conductive layer disposed on the fifth insulation layer, as shown in FIGS. 11A and 11B, FIG. 11B is a schematic plan view of the third conductive layer in FIG. 11A. In an exemplary implementation mode, the second conductive layer may be referred to as a third gate metal (GATE3) layer.

In an exemplary implementation mode, the pattern of the third conductive layer of each circuit unit at least includes a first initial signal line 41, a second initial signal line 42, a third initial signal line 43, a first control signal line 81, and a second control signal line 82.

In an exemplary implementation mode, the first initial signal line 41 may be in a shape of a straight line or a bending line whose main portion extends in the first direction X, the first initial signal line 41 may be located at a side of the second shielding line 32 away from the second plate 72, and a first initial connection block 41-1 is provided at a side of the first initial signal line 41 of each circuit unit away from the second plate 72. A first end of the first initial connection block 41-1 is connected to the first initial signal line 41, a second end of the first initial connection block 41-1 extends in a direction away from the second plate 72, and the first initial connection block 41-1 is configured to be connected to a first region of the first active layer through a seventh connection electrode to be formed subsequently.

In an exemplary implementation mode, an orthographic projection of the first initial signal line 41 on the base substrate at least partially overlaps with an orthographic projection of the third scan signal line 23 on the base substrate, and the first initial signal line 41 with a constant voltage may play a shielding role to reduce influence of the third scan signal line 23 on the pixel drive circuit.

In an exemplary implementation mode, the second initial signal line 42 may be in a shape of a straight line or a bending line whose main portion extends along the first direction X, the second initial signal line 42 may be located at a side of the second scan signal line 22 away from the second plate 72, and a second initial connection block 42-1 is provided at a side of the second initial signal line 42 of each circuit unit close to the second plate 72. A first end of the second initial connection block 42-1 is connected to the second initial signal line 42, a second end of the second initial connection block 42-1 extends in a direction close to the second plate 72, and the second initial connection block 42-1 is configured to be connected to a first region of the seventh active layer through an eighth connection electrode to be formed subsequently.

In an exemplary implementation mode, the third initial signal line 43 may be in a shape of a straight line or a bending line whose main portion extends along the first direction X, the third initial signal line 43 may be located between the light emitting signal line 24 and the second initial signal line 42, and a third initial connection block 43-1 is provided at a side of the third initial signal line 43 of the first circuit unit Q1 away from the second plate 72. A first end of the third initial connection block 43-1 is connected to the third initial signal line 43, a second end of the third initial connection block 43-1 extends in a direction away from the second electrode 72, and the third initial connection block 43-1 is configured to be connected to the first region of the eighth active layer through a ninth connection electrode to be formed subsequently.

In an exemplary implementation mode, an orthographic projection of the third initial signal line 43 on the base substrate at least partially overlaps with an orthographic projection of the second scan signal line 22 on the base substrate, and the third initial signal line 43 with a constant voltage may play a shielding role to reduce influence of the second scan signal line 22 on the pixel drive circuit.

In an exemplary implementation mode, the first control signal line 81 and the second control signal line 82 may be in a shape of a straight line or a bending line whose main portion extends in the first direction X, and the first control signal line 81 and the second control signal line 82 may be located between the first scan signal line 21 and the third scan signal line 23. The first control signal line 81 may be located at a side of the second control signal line 82 close to the first scan signal line 21, and the second control signal line 82 may be located at a side of the first control signal line 81 close to the third scan signal line 23.

In an exemplary implementation mode, a first gate block 81-1 is provided at a side of the first control signal line 81 away from the first scan signal line 21 in the first circuit unit Q1. The first gate block 81-1 may be in a shape of a block (such as a rectangle), a first end of the first gate block 81-1 is connected to the first control signal line 81, a second end of the first gate block 81-1 extends in the direction away from the first scan signal line 21, and a region where the first gate block 81-1 overlaps with the second active layer in the first circuit unit Q1 may serve as a gate electrode of the second transistor T2.

In an exemplary implementation mode, the first control signal line 81 and the first gate block 81-1 may be interconnected to form an integral structure.

In an exemplary implementation mode, an orthographic projection of the first control signal line 81 on the base substrate at least partially overlaps with an orthographic projection of the first shielding line 31 on the base substrate. An orthographic projection of the first gate block 81-1 on the base substrate at least partially overlaps with an orthographic projection of the first shielding block 31-1 on the base substrate. The first control signal line 81 and the first shielding line 31 may be connected to a same signal source so that the first shielding block 31-1 of the first shielding line 31 serves as a bottom gate electrode of the second transistor T2, the first gate block 81-1 of the first control signal line 81 may serve as a top gate electrode of the second transistor T2, to form the second transistor T2 with a top gate and bottom gate structure in the first circuit unit Q1.

In an exemplary implementation mode, a second gate block 82-1 is provided at a side of the second control signal line 82 close to the first scan signal line 21 in the second circuit unit Q2. The second gate block 82-1 may be in a shape of a block (such as a rectangle), a first end of the second gate block 82-1 is connected to the second control signal line 82, a second end of the second gate block 82-1 extends in the direction close to the first scan signal line 21, and a region where the second gate block 82-1 overlaps with the second active layer in the second circuit unit Q2 may serve as a gate electrode of the second transistor T2.

In an exemplary implementation mode, the second control signal line 82 and the second gate block 82-1 may be interconnected to form an integral structure.

In an exemplary implementation mode, an orthographic projection of the second control signal line 82 on the base substrate at least partially overlaps with an orthographic projection of the second shielding line 32 on the base substrate. An orthographic projection of the second gate block 82-1 on the base substrate at least partially overlaps with an orthographic projection of the second shielding block 32-1 on the base substrate. The second control signal line 82 and the second shielding line 32 may be connected to a same signal source such that the second shielding block 32-1 of the second shielding line 32 serves as a bottom gate electrode of the second transistor T2, and the second gate block 82-1 of the second control signal line 82 may serve as a top gate electrode of the second transistor T2, to form the second transistor T2 with a top gate and bottom gate structure in the second circuit unit Q2.

In an exemplary implementation mode, a first region of the fourth active layer (a first electrode of the fourth transistor T4) may be located between the first control signal line 81 and the second control signal line 82.

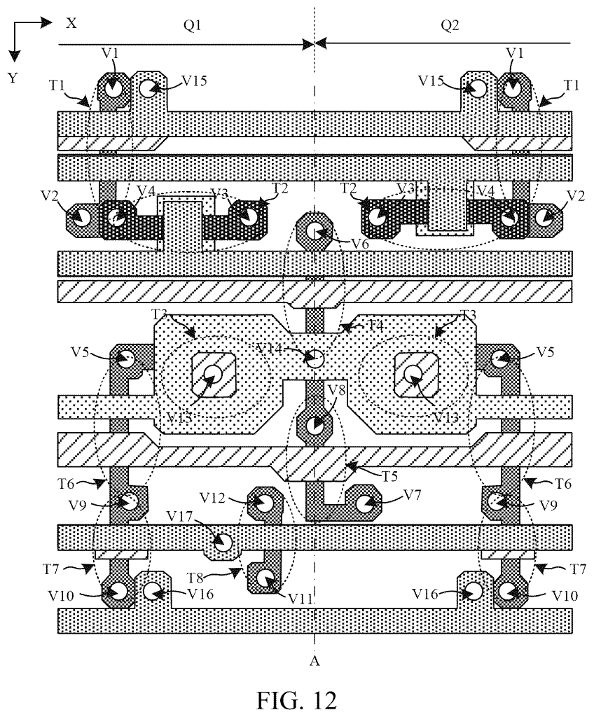

(6) Forming a pattern of a sixth insulation layer. In an exemplary implementation mode, forming the pattern of the sixth insulation layer may include: depositing a sixth insulation thin film on the base substrate on which the aforementioned patterns are formed, patterning the fifth insulation thin film using a patterning process to form a sixth insulation layer covering the third conductive layer, wherein a plurality of vias are provided on the sixth insulation layer, as shown in FIG. 12.

In an exemplary implementation mode, the plurality of vias at least include: a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16 and a seventeenth via V17.

In an exemplary implementation mode, an orthographic projection of the first via V1 on the base substrate is within a range of an orthographic projection of the first region of the first active layer on the base substrate, the sixth insulation layer, the fifth insulation layer, the fourth insulation layer, the third insulation layer and the second insulation layer within the first via V1 are etched away to expose a surface of the first region of the first active layer, and the first via V1 is configured such that the seventh connection electrode to be formed subsequently is connected to the first region of the first active layer through the first via V1. In an exemplary implementation mode, the first via V1 may be provided in each circuit unit.

In an exemplary implementation mode, an orthographic projection of the second via V2 on the base substrate is within a range of an orthographic projection of a second region of the first active layer on the base substrate, the sixth insulation layer, the fifth insulation layer, the fourth insulation layer, the third insulation layer and the second insulation layer within the second via V2 are etched away to expose a surface of the second region of the first active layer, and the second via V2 is configured such that a second connection electrode to be formed subsequently is connected to the second region of the first active layer through the second via V2. In an exemplary implementation mode, the second via V2 may be provided in each circuit unit.

In an exemplary implementation mode, an orthographic projection of the third via V3 on the base substrate is within a range of an orthographic projection of a first region of the second active layer on the base substrate, the sixth insulation layer and the fifth insulation layer within the third via V3 are etched away to expose a surface of the first region of the second active layer, and the third via V3 is configured such that the first connection electrode to be formed subsequently is connected to the first region of the second active layer through the third via V3. In an exemplary implementation mode, the third via V3 may be provided in each circuit unit.

In an exemplary implementation mode, an orthographic projection of the fourth via V4 on the base substrate is within a range of an orthographic projection of a second region of the second active layer on the base substrate, the sixth insulation layer and the fifth insulation layer within the fourth via V4 are etched away to expose a surface of the second region of the second active layer, and the fourth via V4 is configured such that the second connection electrode to be formed subsequently is connected to the second region of the second active layer through the fourth via V4. In an exemplary implementation mode, the fourth via V4 may be provided in each circuit unit.

In an exemplary implementation mode, an orthographic projection of the fifth via V5 on the base substrate is within a range of an orthographic projection of a second region of the third active layer (also a first region of the sixth active layer) on the base substrate, the sixth insulation layer, the fifth insulation layer, the fourth insulation layer, the third insulation layer and the second insulation layer within the fifth via V5 are etched away to expose a surface of the second region of the third active layer (also the first region of the sixth active layer), and the fifth via V5 is configured such that the second connection electrode to be formed subsequently is connected to the second region of the third active layer (also the first region of the sixth active layer) through the fifth via V5. In an exemplary implementation mode, the fifth via V5 may be provided in each circuit unit.

In an exemplary implementation mode, an orthographic projection of the sixth via V6 on the base substrate is within a range of an orthographic projection of a first region of the fourth active layer on the base substrate, the sixth insulation layer, the fifth insulation layer, the fourth insulation layer, the third insulation layer and the second insulation layer within the sixth via V6 are etched away to expose a surface of the first region of the fourth active layer, and the sixth via V6 is configured such that a third connection electrode to be formed subsequently is connected to the first region of the fourth active layer through the sixth via V6.

In an exemplary implementation mode, since the first circuit unit Q1 and the second circuit unit Q2 share the fourth active layer, the first circuit unit Q1 and the second circuit unit Q2 share the sixth via V6, an orthographic projection of the sixth via V6 on the base substrate at least partially overlaps with the orthographic projection of the unit dividing line A on the base substrate, and the sixth via V6 may serve as a second connection via in the present disclosure.

In an exemplary implementation mode, an orthographic projection of the seventh via V7 on the base substrate is within a range of an orthographic projection of a first region of the fifth active layer on the base substrate, the sixth insulation layer, the fifth insulation layer, the fourth insulation layer, the third insulation layer and the second insulation layer within the seventh via V7 are etched away to expose a surface of the first region of the fifth active layer, and the seventh via V7 is configured such that the fourth connection electrode to be formed subsequently is connected to the first region of the fifth active layer through the seventh via V7.

In an exemplary implementation mode, an orthographic projection of the eighth via V8 on the base substrate is within a range of an orthographic projection of a second region of the fifth active layer (also a first region of the third active layer and a second region of the fourth active layer) on the base substrate, the sixth insulation layer, the fifth insulation layer, the fourth insulation layer, the third insulation layer and the second insulation layer within the eighth via V8 are etched away to expose a surface of the second region of the fifth active layer, and the eighth via V8 is configured such that a fifth connection electrode to be formed subsequently is connected to the second region of the fifth active layer (also the first region of the third active layer and the second region of the fourth active layer) through the eighth via V8.

In an exemplary implementation mode, since the first circuit unit Q1 and the second circuit unit Q2 share the fifth active layer, the first circuit unit Q1 and the second circuit unit Q2 share the seventh via V7 and the eighth via V8. The seventh via V7 may be provided in the second circuit unit Q2, an orthographic projection of the eighth via V8 on the base substrate at least partially overlaps with the orthographic projection of the unit dividing line A on the base substrate, and the eighth via V8 may serve as a fourth connection via in the present disclosure.

In an exemplary implementation mode, an orthographic projection of the ninth via V9 on the base substrate is within a range of an orthographic projection of a second region of the sixth active layer (also a second region of the seventh active layer) on the base substrate, the sixth insulation layer, the fifth insulation layer, the fourth insulation layer, the third insulation layer and the second insulation layer within the ninth via V9 are etched away to expose a surface of the second region of the sixth active layer (also a second region of the seventh active layer), and the ninth via V9 is configured such that a sixth connection electrode to be formed subsequently is connected to the second region of the sixth active layer (also the second region of the seventh active layer) through the ninth via V9. In an exemplary implementation mode, the ninth via V9 may be provided in each circuit unit.

In an exemplary implementation mode, an orthographic projection of the tenth via V10 on the base substrate is within a range of an orthographic projection of a first region of the seventh active layer on the base substrate, the sixth insulation layer, the fifth insulation layer, the fourth insulation layer, the third insulation layer and the second insulation layer within the tenth via V10 are etched away to expose a surface of the first region of the seventh active layer, and the tenth via V10 is configured such that an eighth connection electrode to be formed subsequently is connected to the first region of the seventh active layer through the tenth via V10. In an exemplary implementation mode, the tenth via V10 may be provided in each circuit unit.

In an exemplary implementation mode, an orthographic projection of the eleventh via V11 on the base substrate is within a range of an orthographic projection of a first region of the eighth active layer on the base substrate, the sixth insulation layer, the fifth insulation layer, the fourth insulation layer, the third insulation layer and the second insulation layer within the eleventh via V11 are etched away to expose a surface of the first region of the eighth active layer, and the eleventh via V11 is configured such that the ninth connection electrode to be formed subsequently is connected to the first region of the eighth active layer through the eleventh via V11.

In an exemplary implementation mode, an orthographic projection of the twelfth via V12 on the base substrate is within a range of an orthographic projection of a second region of the eighth active layer on the base substrate, the sixth insulation layer, the fifth insulation layer, the fourth insulation layer, the third insulation layer and the second insulation layer within the twelfth via V12 are etched away to expose a surface of the second region of the eighth active layer, and the twelfth via V12 is configured such that a fifth connection electrode to be formed subsequently is connected to the second region of the eighth active layer through the twelfth via V12.

In an exemplary implementation mode, since the first circuit unit Q1 and the second circuit unit Q2 share the eighth active layer, the first circuit unit Q1 and the second circuit unit Q2 share the eleventh via V11 and the twelfth via V12, and the eleventh via V11 and the twelfth via V12 may be provided in the first circuit unit Q1.

In an exemplary implementation mode, an orthographic projection of the thirteenth via V13 on the base substrate is within a range of the orthographic projection of the opening 73 on the base substrate, the sixth insulation layer, the fifth insulation layer, the fourth insulation layer and the third insulation layer in the thirteenth via V13 are etched away to expose a surface of the first plate 71, and the thirteenth via V13 is configured such that the first connection electrode to be formed subsequently is connected to the first plate 71 through the thirteenth via V13. In an exemplary implementation mode, the thirteenth via V13 may be provided in each circuit unit.

In an exemplary implementation mode, an orthographic projection of the fourteenth via V14 on the base substrate is within a range of an orthographic projection of the plate connection strip 74 of the second plate 72 on the base substrate, the sixth insulation layer, the fifth insulation layer and the fourth insulation layer in the fourteenth via V14 are etched away to expose a surface of the plate connection strip 74, and the fourteenth via V14 is configured such that the fourth connection electrode to be formed subsequently is connected to the plate connection strip 74 through the fourteenth via V14.

In an exemplary implementation mode, the fourteenth via V14 may be located on the unit dividing line A, an orthographic projection of the fourteenth via V14 on the base substrate at least partially overlaps with the orthographic projection of the unit dividing line A on the base substrate, and the first circuit unit Q1 and the second circuit unit Q2 share one fourteenth via V14.

In an exemplary implementation mode, an orthographic projection of the fifteenth via V15 on the base substrate is within a range of an orthographic projection of the first initial connection block 41-1 of the first initial signal line 41 on the base substrate, the sixth insulation layer in the fifteenth via V15 is etched away to expose a surface of the first initial connection block 41-1, and the fifteenth via V15 is configured such that the seventh connection electrode to be formed subsequently is connected to the first initial connection block 41-1 through the fifteenth via V15. In an exemplary implementation mode, the fifteenth via V15 may be provided in each circuit unit.

In an exemplary implementation mode, an orthographic projection of the sixteenth via V16 on the base substrate is within a range of an orthographic projection of the second initial connection block 42-1 of the second initial signal line 42 on the base substrate, the sixth insulation layer in the sixteenth via V16 is etched away to expose a surface of the second initial connection block 42-1, and the sixteenth via V16 is configured such that the eighth connection electrode to be formed subsequently is connected to the second initial connection block 42-1 through the sixteenth via V16. In an exemplary implementation mode, the sixteenth via V16 may be provided in each circuit unit.

In an exemplary implementation mode, an orthographic projection of the seventeenth via V17 on the base substrate is within a range of an orthographic projection of the third initial connection block 43-1 of the third initial signal line 43 on the base substrate, the sixth insulation layer in the seventeenth via V17 is etched away to expose a surface of the third initial connection block 43-1, and the seventeenth via V17 is configured such that the ninth connection electrode to be formed subsequently is connected to the third initial connection block 43-1 through the seventeenth via V17.

In an exemplary implementation mode, since the first circuit unit Q1 and the second circuit unit Q2 share the eighth active layer, the first circuit unit Q1 and the second circuit unit Q2 share the seventeenth via V17, and the seventeenth via V17 may be provided in the first circuit unit Q1.

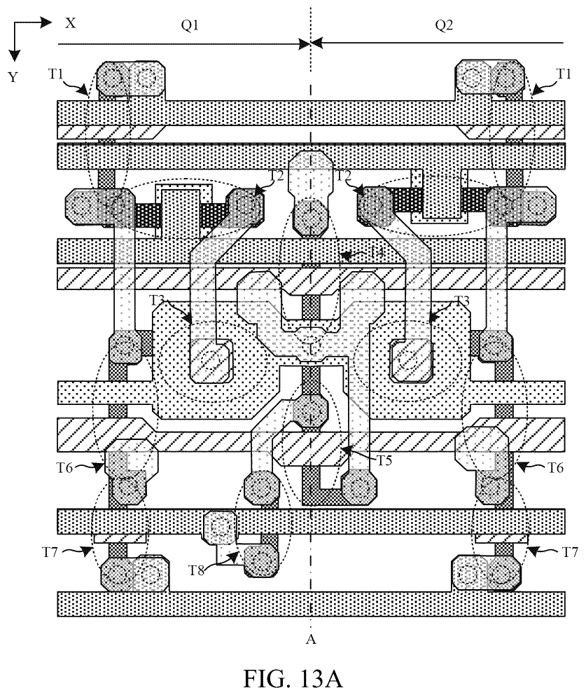

(7) Forming a pattern of a fourth conductive layer. In an exemplary implementation mode, forming the pattern of the fourth conductive layer may include: depositing a fourth conductive thin film on the base substrate on which the aforementioned patterns are formed, and patterning the fourth conductive thin film through a patterning process to form the fourth conductive layer disposed on the sixth insulation layer, as shown in FIG. 13A and FIG. 13B, and FIG. 13B is a schematic plan view of the fourth conductive layer in FIG. 13A. In an exemplary implementation mode, the fourth conductive layer may be referred to as a first source drain metal (SD1) layer.

In an exemplary implementation mode, the fourth conductive layer may at least include: the first connection electrode 51, the second connection electrode 52, the third connection electrode 53, the fourth connection electrode 54, the fifth connection electrode 55, the sixth connection electrode 56, the seventh connection electrode 57, the eighth connection electrode 58 and the ninth connection electrode 59.

In an exemplary implementation mode, the first connection electrode 51 may be in a shape of a bending line whose main portion extends in the second direction Y, a first end of the first connection electrode 51 is connected to the first region of the second active layer through the third via V3, and a second end of the first connection electrode 51, after extending along the second direction Y, is connected to the first plate 71 through the thirteenth via V13. In an exemplary implementation mode, the first connection electrode 51 may be provided in each circuit unit.

In an exemplary implementation mode, since the first plate 71 simultaneously serves as the gate electrode of the third transistor T3, the first connection electrode 51 enables the first electrode of the second transistor T2, the gate electrode of the third transistor T3 and the first plate 71 to have a same potential to form a first node N1 of the pixel drive circuit.

In an exemplary implementation mode, the second connection electrode 52 may be in a shape of an “L”, a first end of the second connection electrode 52 is connected to the second region of the first active layer through the second via V2, a second end of the second connection electrode 52 is connected to the second region of the third active layer (also the first region of the sixth active layer) through the fifth via V5, and a region between the first and second ends of the second connection electrode 52 is connected to the second region of the second active layer through the fourth via V4. In an exemplary implementation mode, the second connection electrode 52 may be provided in each circuit unit.

In an exemplary implementation mode, the second connection electrode 52 enables the second electrode of the first transistor T1, the second electrode of the second transistor T2, the second electrode of the third transistor T3, and the first electrode of the sixth transistor T6 to have a same potential to form a third node N3 of the pixel drive circuit.

In an exemplary implementation mode, the third connection electrode 53 may be in a shape of a block (such as a rectangle) and the third connection electrode 53 is connected to the first region of the fourth active layer through the sixth via V6. In an exemplary implementation mode, the third connection electrode 53 may serve as the first electrode of the fourth transistor T4, and the third connection electrode 53 is configured to be connected to a data signal line to be formed subsequently.

In an exemplary implementation mode, since the first circuit unit Q1 and the second circuit unit Q2 share the sixth via V6, the first circuit unit Q1 and the second circuit unit Q2 share the third connection electrode 53. An orthographic projection of the third connection electrode 53 on the base substrate at least partially overlaps with the orthographic projection of the unit dividing line A on the base substrate, and the third connection electrode 53 may serve as a data connection electrode in the present disclosure.

In an exemplary implementation mode, the fourth connection electrode 54 may include a first sub-electrode 54-1 and a second sub-electrode 54-2. The first sub-electrode 54-1 may be in a shape of a strip whose main portion extends in the second direction Y, a first end of the first sub-electrode 54-1 is connected to the first region of the fifth active layer through the seventh via V7, and a second end of the fourth connection electrode 54, after extending in a direction towards the second plate 72, is connected to the second sub-electrode 54-2. The second sub-electrode 54-2 may be in a shape of a “U”, and a middle portion of the second sub-electrode 54-2 in the first direction X is connected to the plate connection strip 74 through the fourteenth via V14. Since the plate connection strip 74 is connected to the second plates 72 in the first circuit unit Q1 and the second circuit unit Q2 respectively, the first electrode of the fifth transistor T5 and the second plate 72 of the storage capacitor in each circuit unit can have a same potential.

In an exemplary implementation mode, the first sub-electrode 54-1 and the second sub-electrode 54-2 may be interconnected to form an integral structure.

In an exemplary implementation mode, since the first circuit unit Q1 and the second circuit unit Q2 share the seventh via V7 and the fourteenth via V14, the first circuit unit Q1 and the second circuit unit Q2 share the fourth connection electrode 54. The fourth connection electrode 54 may serve as a power supply connection electrode in the present disclosure, and an orthographic projection of the fourth connection electrode 54 on the base substrate at least partially overlaps with the orthographic projection of the unit dividing line A on the base substrate. In an exemplary implementation mode, the first sub-electrode 54-1 may be disposed in the second circuit unit Q2, an orthographic projection of the second sub-electrode 54-2 on the base substrate at least partially overlaps with the orthographic projection of the unit dividing line A on the base substrate, and two ends of the second sub-electrode 54-2 in the first direction X are disposed in the first circuit unit Q1 and the second circuit unit Q2 respectively.

In an exemplary implementation mode, the fifth connection electrode 55 may be in a shape of a bending line, a first end of the fifth connection electrode 55 is connected to the second region of the fifth active layer through the eighth via V8, and a second end of the fifth connection electrode 55 is connected to the second region of the eighth active layer through the twelfth via V12. In an exemplary implementation mode, since the second region of the fifth active layer serves as the first region of the third active layer and the second region of the fourth active layer at the same time, the fifth connection electrode 55 enables the first electrode of the third transistor T3, the second electrode of the fourth transistor T4, the second electrode of the fifth transistor T5 and the second electrode of the eighth transistor T8 to have a same potential to form a second node N2 of the pixel drive circuit.

In an exemplary implementation mode, since the first circuit unit Q1 and the second circuit unit Q2 share the eighth via V8 and the twelfth via V12, the first circuit unit Q1 and the second circuit unit Q2 share the fifth connection electrode 55. The fifth connection electrode 55 may be provided in the first circuit unit Q1, the fifth connection electrode 55 may serve as an initial connection electrode in the present disclosure, and an orthographic projection of the fifth connection electrode 55 on the base substrate at least partially overlaps with the orthographic projection of the unit dividing line A on the base substrate.

In an exemplary implementation mode, the sixth connection electrode 56 may be in a shape of a block (such as a rectangle), and the sixth connection electrode 56 is connected to the second region of the sixth active layer (also the second region of the seventh active layer) through the ninth via V9. In an exemplary implementation mode, the sixth connection electrode 56 may serve as the second electrode of the sixth transistor T6 and the second electrode of the seventh transistor T7 simultaneously, and the sixth connection electrode 56 is configured to be connected to an anode connection electrode to be formed subsequently. In an exemplary implementation mode, the sixth connection electrode 56 may be provided in each circuit unit.

In an exemplary implementation mode, the seventh connection electrode 57 may be in a shape of a block (such as a rectangle), a first end of the seventh connection electrode 57 is connected to the first region of the first active layer through the first via V1, and a second end of the seventh connection electrode 57 is connected to the first initial connection block 41-1 through the fifteenth via V15. In an exemplary implementation mode, the seventh connection electrode 57 may serve as the first electrode of the first transistor T1, and since the first initial connection block 41-1 is connected to the first initial signal line 41, the seventh connection electrode 57 enables a first initial signal transmitted by the first initial signal line 41 to be written to the first electrode of the first transistor T1. In an exemplary implementation mode, the seventh connection electrode 57 may be provided in each circuit unit.

In an exemplary implementation mode, the eighth connection electrode 58 may be in a shape of a block (such as a rectangle), a first end of the eighth connection electrode 58 is connected to the first region of the seventh active layer through the tenth via V10, and a second end of the eighth connection electrode 58 is connected to the second initial connection block 42-1 through the sixteenth via V16. In an exemplary implementation mode, the eighth connection electrode 58 may serve as the first electrode of the seventh transistor T7, and since the second initial connection block 42-1 is connected to the second initial signal line 42, the eighth connection electrode 58 enables a second initial signal transmitted by the second initial signal line 42 to be written to the first electrode of the seventh transistor T7. In an exemplary implementation mode, the eighth connection electrode 58 may be provided in each circuit unit.

In an exemplary implementation mode, the ninth connection electrode 59 may be in a shape of an “L”, a first end of the ninth connection electrode 59 is connected to the first region of the eighth active layer through the eleventh via V11, and a second end of the ninth connection electrode 59 is connected to the third initial connection block 43-1 through the seventeenth via V17. The ninth connection electrode 59 may serve as the first electrode of the eighth transistor T8, and since the third initial connection block 43-1 is connected to the third initial signal line 43, the ninth connection electrode 59 enables a third initial signal transmitted by the third initial signal line 43 to be written to the first electrode of the eighth transistor T8. In an exemplary implementation mode, the ninth connection electrode 59 may be provided in each circuit unit.

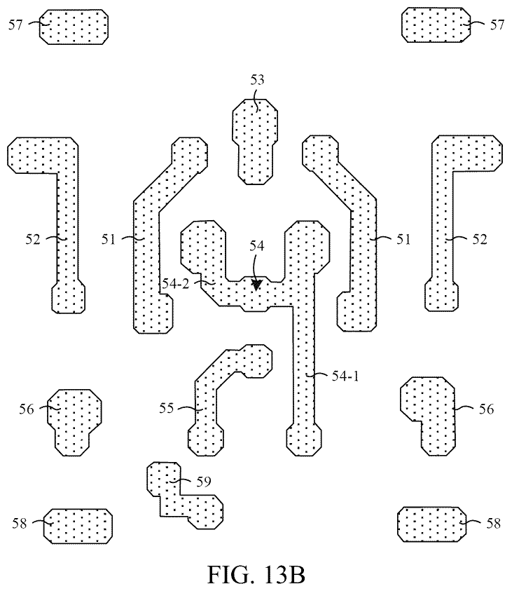

(8) Forming a pattern of a first planarization layer. In an exemplary implementation mode, forming the pattern of the first planarization layer may include: coating a first planarization thin film on the base substrate on which the aforementioned patterns are formed, patterning the first planarization thin film using a patterning process to form a first planarization layer covering the pattern of the fourth conductive layer, wherein the first planarization layer is provided with a plurality of vias, as shown in FIG. 14.

In an exemplary implementation mode, the plurality of vias at least include a twenty-first via V21, a twenty-second via V22, and a twenty-third via V23.

In an exemplary implementation mode, an orthographic projection of the twenty-first via V21 on the base substrate is located within a range of the orthographic projection of the third connection electrode 53 on the base substrate, the first planarization layer in the twenty-first via V21 is etched away to expose a surface of the third connection electrode 53, and the twenty-first via V21 is configured such that the data signal line to be formed subsequently is connected to the third connection electrode 53 through the twenty-first via V21. In an exemplary implementation mode, since the first circuit unit Q1 and the second circuit unit Q2 share the third connection electrode 53, and the first circuit unit Q1 and the second circuit unit Q2 share the twenty-first via V21. The twenty-first via V21 may serve as a first connection via in the present disclosure, and an orthographic projection of the twenty-first via V21 on the base substrate at least partially overlaps with the orthographic projection of the unit dividing line A on the base substrate.

In an exemplary implementation mode, an orthographic projection of the twenty-second via V22 on the base substrate is within a range of the orthographic projection of the second sub-electrode 54-2 in the fourth connection electrode 54 on the base substrate, the first planarization layer in the twenty-second via V22 is etched away to expose a surface of the second sub-electrode 54-2, and the twenty-second via V22 is configured such that a first power supply line to be formed subsequently is connected to the second sub-electrode 54-2 through the twenty-second via V22. In an exemplary implementation mode, although the first circuit unit Q1 and the second circuit unit Q2 share the fourth connection electrode 54, the twenty-second via V22 may be provided in each circuit unit, one twenty-second via V22 may be provided at an end of the second sub-electrode 54-2 in an opposite direction of the first direction X, and is located in the first circuit unit Q1, and another twenty-second via V22 may be provided at an end of the second sub-electrode 54-2 in the first direction X, and is located in the second circuit unit Q2. The twenty-second via V22 may serve as a third connection via in the present disclosure, and an orthographic projection of the third connection via on the base substrate does not overlap with the orthographic projection of the unit dividing line A on the base substrate.

In an exemplary implementation mode, an orthographic projection of the twenty-third via V23 on the base substrate is within a range of an orthographic projection of the sixth connection electrode 56 on the base substrate, the first planarization layer in the twenty-third via V23 is etched away to expose a surface of the sixth connection electrode 56, and the twenty-third via V23 is configured such that the anode connection electrode to be formed subsequently is connected to the sixth connection electrode 56 through the twenty-third via V23. In an exemplary implementation mode, the twenty-third via V23 may be provided in each circuit unit.

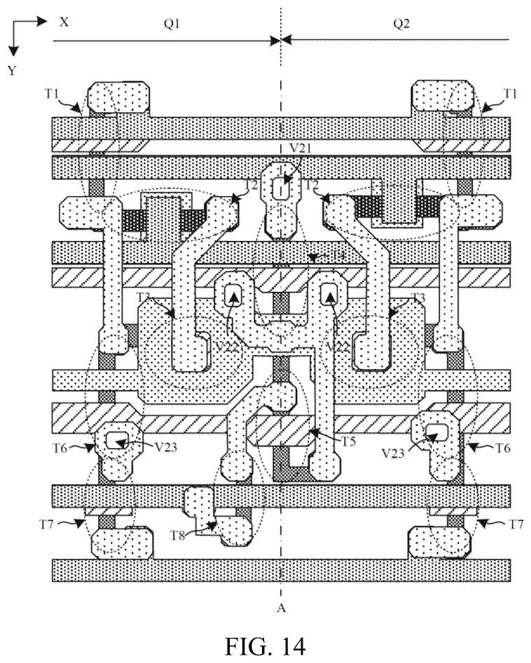

(9) Forming a pattern of a fifth conductive layer. In an exemplary implementation mode, forming the pattern of the fifth conductive layer may include: depositing a fifth conductive thin film on the base substrate on which the above-mentioned patterns are formed, and patterning the fifth conductive thin film using a patterning process to form the fifth conductive layer disposed on the first planarization layer, as shown in FIG. 15A and FIG. 15B, and FIG. 15B is a schematic plan view of the fifth conductive layer in FIG. 15A. In an exemplary implementation mode, the fifth conductive layer may be referred to as a second source-drain metal (SD2) layer.

In an exemplary implementation mode, the fifth conductive layer at least includes the first power supply line 61, the data signal line 62 and the anode connection electrode 63.

In an exemplary implementation mode, the first power supply line 61 may be in a shape of a straight line or a bending line whose main portion extends in the second direction Y, and the first power supply line 61 is connected to the fourth connection electrode 54 through the twenty-second via V22. Since the fourth connection electrode 54 is connected to the first region of the fifth active layer and the second plate 72 of the storage capacitor respectively, the first power supply line 61 can write a first power supply signal to the fifth transistor T5 and the second plate 72 of the storage capacitor. In an exemplary implementation mode, the first power supply line 61 may be provided in each circuit unit.

In an exemplary implementation mode, the first power supply line 61 may be of a bending line with unequal widths, which may not only facilitate a layout of a pixel structure, but also reduce a parasitic capacitance between the first power supply line and a data signal line.

In an exemplary implementation mode, the first power supply line 61 is connected to a power supply connection block 61-1, the power supply connection block 61-1 may be in a shape of a block (e.g., a rectangle), and the power supply connection block 61-1 is connected to the second sub-electrode 54-2 in each circuit unit through the twenty-second via V22. Since the second sub-electrodes 54-2 in the first circuit unit Q1 and the second circuit unit Q2 are both connected to the first sub-electrode 54-1, and the first sub-electrode 54-1 is connected to the first electrode of the fifth transistor T5 shared by the first circuit unit Q1 and the second circuit unit Q2, the fourth connection electrode 54 enables the first power supply line 61 in the first circuit unit Q1 and the first power supply line 61 in the second circuit unit Q2 to be connected to each other, so that a plurality of first power supply lines 61 in one unit row can be ensured to have a same potential, which is beneficial for improving uniformity of the display substrate, avoiding poor display of the display substrate and ensuring the display effect of the display substrate.

In an exemplary implementation mode, the first power supply line 61 is connected to a shielding block 61-2, the shielding block 61-2 may be a in a shape of block (such as a rectangle). An orthographic projection of the shielding block 61-2 on the base substrate at least partially overlaps with an orthographic projection of the second active layer on the base substrate, so that the shielding block 61-2 can shield the second active layer, block light emitted by a light emitting device and light reflected by a film layer from irradiating the second transistor T2 made of oxide, and prevent the oxide transistor from characteristic drift due to illumination, thus improving electrical characteristics of the oxide transistor.

In an exemplary implementation mode, orthographic projections of the first power supply line 61 and the shielding block 61-2 on the base substrate at least partially overlap with an orthographic projection of the first connection electrode 51 on the base substrate, and the first power supply line 61 and the shielding block 61-2 with a constant potential can effectively shield influence of data voltage jump and other signals on the first node N1 in the pixel drive circuit, avoid the influence of the data voltage jump and other signals on the potential of the first node N1, and improve driving performance of the pixel drive circuit.

In an exemplary implementation mode, orthographic projections of the first power supply line 61 and the shielding block 61-2 on the base substrate at least partially overlap with an orthographic projection of the second connection electrode 52 on the base substrate, and the first power supply line 61 and the shielding block 61-2 with a constant potential can effectively shield influence of data voltage jump and other signals on the third node N3 in the pixel drive circuit, avoid the influence of the data voltage jump and other signals on the potential of the third node N3, and improve the driving performance of the pixel drive circuit.

In the exemplary implementation mode, the data signal line 62 may be in a shape of a straight line or a bending line whose main portion extends along the second direction Y, and the data signal line 62 is connected to the third connection electrode 53 through the twenty-first via V21. Since the third connection electrode 53 is connected to the first region of the fourth active layer through the sixth via V6, connection between the data signal line 62 and the first electrode of the fourth transistor T4 is achieved, and the data signal line 62 can write a data signal to the first electrode of the fourth transistor T4.

In an exemplary implementation mode, since the first circuit unit Q1 and the second circuit unit Q2 share the twenty-first via V21, the first circuit unit Q1 and the second circuit unit Q2 share the data signal line 62, and an orthographic projection of the data signal line 62 on the base substrate at least partially overlaps with the orthographic projection of the unit dividing line A on the base substrate.

In an exemplary implementation mode, the anode connection electrode 63 may be in a shape of a block (e.g., a rectangle), the anode connection electrode 63 is connected to the sixth connection electrode 56 through the twenty-third via V23, and the anode connection electrode 63 is configured to be connected to an anode to be formed subsequently. Since the sixth connection electrode 56 is connected to the second region of the sixth active layer and a second region of the seventh active layer through the ninth via V9, connection between the anode to be formed subsequently and the second electrode of the sixth transistor T6 as well as the second electrode of the seventh transistor T7 can be achieved, and the pixel drive circuit can drive the light emitting device to emit light. In an exemplary implementation mode, the anode connection electrode 63 may be provided in each circuit unit.

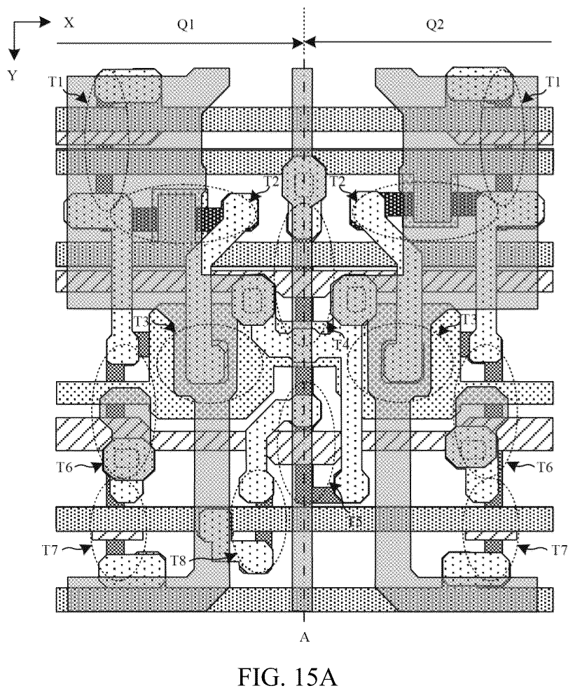

(10) Forming a pattern of a second planarization layer. In an exemplary implementation mode, forming the pattern of the second planarization layer may include: coating a second planarization thin film on the base substrate on which the aforementioned patterns are formed, patterning the first planarization thin film through a patterning process to form the second planarization layer covering the pattern of the fifth conductive layer, wherein the second planarization layer is provided with a plurality of vias, as shown in FIG. 16.

In an exemplary implementation mode, the plurality of vias at least include an anode connection via V30. An orthographic projection of the anode connection via V30 on the base substrate is within a range of an orthographic projection of the anode connection electrode 63 on the base substrate. The second planarization layer in the anode connection via V30 is etched away to expose a surface of the anode connection electrode 63. The anode connection via V30 is configured such that the anode to be formed subsequently is connected to the anode connection electrode 63 through the anode connection via V30. In an exemplary implementation mode, the anode connection via V30 may be provided in each circuit unit.

So far, the drive circuit layer has been manufactured on the base substrate. In a plane parallel to the display substrate, the drive circuit layer may include a plurality of circuit units, each circuit unit may include a pixel drive circuit, and a first scan signal line, a second scan signal line, a third scan signal line, a control signal line, a light emitting signal line, a data signal line, a first power supply line, a first initial signal line, a second initial signal line, and a third initial signal line which are connected to the pixel drive circuit. In a plane perpendicular to the display substrate, the drive circuit layer may include a first insulation layer, a first semiconductor layer, a second insulation layer, a first conductive layer, a third insulation layer, a second conductive layer, a fourth insulation layer, a second semiconductor layer, a fifth insulation layer, a third conductive layer, a sixth insulation layer, a fourth conductive layer, a first planarization layer, a fifth conductive layer and a second planarization layer which are arranged sequentially on the base substrate. The first semiconductor layer may at least include active layers of the first transistor, the third transistor to the eighth transistor. The first conductive layer may at least include a first scan signal line, a second scan signal line, a third scan signal line, a light emitting signal line and a first plate of the storage capacitor. The second conductive layer may at least include a first shielding line, a second shielding line and a second plate of the storage capacitor. The second semiconductor layer may at least include an active layer of the second transistor. The third conductive layer may at least include a first initial signal line, a second initial signal line, a third initial signal line, a first control signal line and a second control signal line. The fourth conductive layer may at least include a plurality of connection electrodes. The fifth conductive layer may at least include a first power supply line, a data signal line and an anode connection electrode.

In an exemplary implementation mode, the base substrate may be a flexible base substrate, or a rigid base substrate. The rigid base substrate may include, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In an exemplary implementation mode, the flexible base substrate may include a first flexible material layer, a first inorganic material layer, a semiconductor layer, a second flexible material layer, and a second inorganic material layer which are stacked. Materials of the first flexible material layer and the second flexible material layer may be Polyimide (PI), Polyethylene Terephthalate (PET), or surface treated polymer soft film, etc., and materials of the first inorganic material layer and the second inorganic material layer may be Silicon Nitride (SiNₓ), Silicon Oxide (SiOₓ), or the like, for improving water and oxygen resistance of the base substrate. The first inorganic material layer and the second inorganic material layer may also be referred to as barrier layers, and the material of the semiconductor layer may be amorphous silicon (a-si).

In an exemplary implementation mode, the first conductive layer, the second conductive layer, the third conductive layer, the fourth conductive layer, and the fifth conductive layer may be made of a metal material, such as any one or more of Argentum (Ag), Copper (Cu), Aluminum (Al), and Molybdenum (Mo), or an alloy material of the aforementioned metals, such as an Aluminum-Neodymium alloy (AlNd) or a Molybdenum-Niobium alloy (MoNb), and may be in a single-layer structure, or a multi-layer composite structure such as Mo/Cu/Mo. The first insulation layer, the second insulation layer, the third insulation layer, the fourth insulation layer, the fifth insulation layer, and the sixth insulation layer may be made of any one or more of Silicon Oxide (SiOₓ), Silicon Nitride (SiNₓ), and Silicon OxyNitride (SiON), and may be a single layer, multiple layers, or a composite layer. The first planarization layer and the second planarization layer may be made of an organic material, such as resin.

In an exemplary implementation mode, after the drive circuit layer is manufactured, a light emitting structure layer may be manufactured. In an exemplary implementation mode, manufacturing of the light emitting structure layer may include following operations.

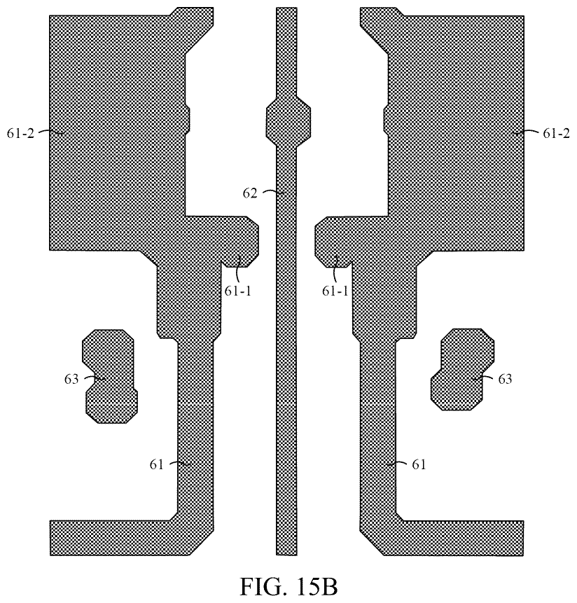

(11) Forming a pattern of an anode conductive layer. In an exemplary implementation mode, forming the pattern of the anode conductive layer may include depositing an anode conductive thin film on the base substrate on which the above-mentioned patterns are formed, patterning the anode conductive thin film using a patterning process to form the anode conductive layer disposed on the second planarization layer, as shown in FIG. 17.

In an exemplary implementation mode, the anode conductive layer at least includes a plurality of anodes 90, and each anode 90 may include an anode body part 90-1 and an anode connection part 90-2 connected to each other. The anode body part 90-1 may be in a shape of a circle or an ellipse, and the anode connection part 90-2 may be in a shape of a strip. A first end of the anode connection part 90-2 is connected to the anode body part 90-1, and a second end of the anode connection part 90-2, after extending in a direction away from the anode body part 90-1, is connected to the anode connection electrode 63 through the anode connection via V30.

In an exemplary implementation mode, the anode conductive layer may be in a single-layer structure, such as Indium Tin Oxide (ITO) or Indium Zinc Oxide (IZO), or may be in a multi-layer composite structure, such as ITO/Ag/ITO.

In an exemplary implementation mode, a subsequent manufacturing process may include: forming a pattern of a pixel definition layer at first, then forming an organic light emitting layer using an evaporation process and inkjet printing process, then forming a cathode on the organic light emitting layer.

In an exemplary implementation mode, after the manufacturing of the light emitting structure layer is completed, an encapsulation structure layer can be manufactured, wherein the encapsulation structure layer may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is provided between the first encapsulation layer and the third encapsulation layer, which can ensure that external moisture cannot enter the light emitting structure layer.

In a display substrate, since the pixel drive circuit of each circuit unit includes eight transistors and one storage capacitor, it is difficult to reduce the size of the circuit unit, and it is difficult to improve a resolution (Pixels Per Inch, PPI for short) of a display apparatus. In addition, the increase in resolution requires a reduction in the size of the circuit unit, and as the size of the circuit unit is reduced, distances between nodes and distances between nodes and signal lines in the pixel drive circuit are reduced, resulting in an increase in capacitances between signals, and there is a crosstalk defect, which may even cause deterioration in the display effect.

The display substrate according to the embodiment of the present disclosure can effectively reduce the size of the circuit unit and effectively improve the resolution of the display apparatus by providing two circuit units sharing one data signal line, one fourth transistor T4, one fifth transistor T5 and one eighth transistor T8. The display substrate according to the present disclosure provides a data signal line, a fourth transistor T4, and a fifth transistor T5 between two circuit units, and provides an eighth transistor T8 near a unit dividing line A, such that one data signal line can supply data signals to pixel drive circuits in two unit columns through one fourth transistor T4 respectively, and the two circuit units include only 13 transistors, 2 storage capacitors, and one data signal line. Compared with the existing structure in which two circuit units include 16 transistors, 2 storage capacitors and two data signal lines, the present disclosure effectively reduces the quantity of transistors and the quantity of data signal lines in the circuit unit, reduces the area occupied by the pixel drive circuits, simplifies the structure of the pixel drive circuits, thereby effectively reducing the size of each circuit unit and effectively improving the resolution of the display apparatus, and ensuring the distances between nodes and the distances between nodes and the signal lines in the pixel drive circuits, effectively avoiding crosstalk defect, effectively improving the display quality of the display apparatus, effectively improving a yield of products and reducing a production cost.

In the display substrate according to the embodiment of the present disclosure, by providing two circuit units to share one data signal line, the quantity of data channels in a data drive chip can also be reduced, which can effectively reduce a cost of the data drive chip and reduce the product cost.

In the present disclosure, by providing the first power supply line to cover the first connection electrode, the influence of data voltage jump and other signals on the first node in the pixel drive circuit can be effectively shielded, thus avoiding the influence of data voltage jump and other signals on the potential of the first node, and effectively avoiding the deterioration of crosstalk. In the present disclosure, by arranging the first power supply line to cover the second active layer, light emitted by a light emitting device and light reflected by a film layer can be blocked from irradiating the oxide transistor, the oxide transistor can be prevented from characteristic drift due to illumination, thus improving electrical characteristics of the oxide transistor. The manufacturing process in the present disclosure may be compatible well with an existing manufacturing process, is simple in process implementation, is easy to implement, and has a high production efficiency, a low production cost, and a high yield.

The aforementioned structure shown in the present disclosure and the manufacturing process thereof are merely exemplary description. In an exemplary implementation mode, corresponding structures may be changed and patterning processes may be added or reduced according to actual needs, which is not limited here in the present disclosure.

In an exemplary implementation mode, the display substrate according to the present disclosure may be applied to a display device with a pixel drive circuit, such as an OLED, a quantum dot display (QLED), a light emitting diode display (Micro LED or Mini LED), or a Quantum Dot Light Emitting Diode display (QDLED), etc., which is not limited here in the present disclosure.

An exemplary embodiment of the present disclosure further provides a drive method of a display substrate for driving the above-mentioned display substrate. In an exemplary implementation mode, the display substrate includes a plurality of circuit units constituting a plurality of unit rows and a plurality of unit columns. At least one of the circuit units at least includes a pixel drive circuit, and at least one pixel drive circuit at least includes a data writing transistor connected to a data signal line. The plurality of circuit units at least include a first circuit unit and a second circuit unit adjacent in a unit row direction, the first circuit unit includes a first pixel drive circuit, the second circuit unit includes a second pixel drive circuit, and the first pixel drive circuit and the second pixel drive circuit share a same data writing transistor and a same data signal line; the drive method may include:

The data signal line provides a first data signal to the first pixel drive circuit and provides a second data signal to the second pixel drive circuit through the data writing transistor sequentially.

In an exemplary implementation mode, the display substrate further includes a first control signal line and a second control signal line. The first pixel drive circuit further includes a first compensation transistor, a first drive transistor and a first storage capacitor, a gate electrode of the first compensation transistor is connected to the first control signal line, a first electrode of the first compensation transistor is respectively connected to a gate electrode of the first drive transistor and the first storage capacitor, a second electrode of the first compensation transistor is connected to a second electrode of the first drive transistor, a first electrode of the first drive transistor is connected to the data writing transistor. The second pixel drive circuit further includes a second compensation transistor, a second drive transistor and a second storage capacitor, a gate electrode of the second compensation transistor is connected to the second control signal line, a first electrode of the second compensation transistor is respectively connected to a gate electrode of the second drive transistor and the second storage capacitor, a second electrode of the second compensation transistor is connected to a second electrode of the second drive transistor, a first electrode of the second drive transistor is connected to the data writing transistor.

In an exemplary implementation mode, the drive method may include:
B11, the first control signal line provides a turned-on signal, the second control signal line provides a turned-off signal, the first compensation transistor is turned on to initialize the first storage capacitor;
B12, the first control signal line provides a turned-off signal, the second control signal line provides a turned-on signal, the second compensation transistor is turned on to initialize the second storage capacitor;
B13, the first control signal line provides a turned-on signal, the second control signal line provides a turned-off signal, the first compensation transistor is turned on, and the data signal line provides a first data signal to the first storage capacitor through the data writing transistor, the first drive transistor, and the first compensation transistor;
B14, the first control signal line provides a turned-off signal, the second control signal line provides a turned-on signal, the second compensation transistor is turned on, and the data signal line provides a second data signal to the second storage capacitor through the data writing transistor, the second drive transistor, and the second compensation transistor.

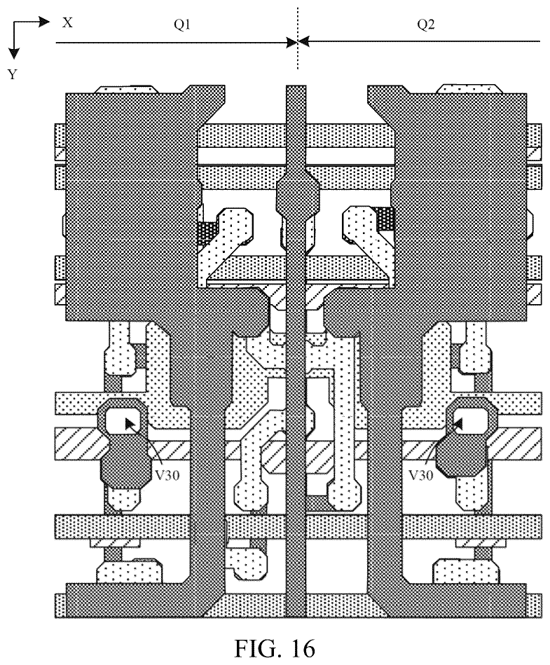

FIG. 18 is a driving timing diagram of a pixel drive circuit according to an exemplary embodiment of the present disclosure. As shown in FIG. 18, a working process of the pixel drive circuit shown in FIG. 4 may include following stages.

A first stage A1 may be referred to as a reset stage for the second node N2 and the fourth node N4. In this stage, signals of the first control signal line KS1, the second control signal line KS2 and the second scan signal line S2 are low-level signals, and signals of the first scan signal line S1, the third scan signal line S3 and the light emitting signal line EM are high-level signals, so that the seventh transistor T7 of each pixel drive circuit is turned on, the eighth transistor T8 shared by two pixel drive circuits is turned on, and other transistors are turned off.

The seventh transistor T7 of each pixel drive circuit is turned on, so that a signal of the second initial signal line IN1T2 is provided to the fourth node N4, to initialize (reset) a first electrode of the light emitting device EL, and clear original charge in the first electrode of the light emitting device EL, so that a potential of the fourth node N4 is Vinit2. The eighth transistor T8 shared by the two pixel drive circuits is turned on so that a signal of the third initial signal line IN1T3 is provided to the second node N2, to initialize (reset) the second node N2, and clear original charge in the second node N2, so that a potential of the second node N2 is Vinit3.

A second stage A2 may be referred to as a reset stage for the first node N1 of the first pixel drive circuit. In this stage, signals of the second control signal line KS2 and the third scan signal line S3 are low-level signals, and signals of the first control signal line KS1, the first scan signal line S1, the second scan signal line S2 and the light emitting signal line EM are high-level signals, so that the first transistor T1 of each pixel drive circuit and the second transistor T2 of the first pixel drive circuit are turned on and the other transistors are turned off.

The first transistor T1 of each pixel drive circuit is turned on so that a signal of the first initial signal line IN1T1 is provided to the third node N3, to initialize (reset) the third node N3, and clear original charge in the third node N3, so that a potential of the third node N3 is Vinit1. The second transistor T2 of the first pixel drive circuit is turned on so that the first node N1 and the third node N3 are turned on, to initialize (reset) the first node N1 of the first pixel drive circuit, and clear original charge in the first node N1, a potential of the first node N1 is Vinit1. In this stage, the third transistor T3 of the first pixel drive circuit is turned on, and a signal of the second node N2 can be provided to the first node N1 and the third node N3.

A third stage A3 may be referred to as a reset stage for the first node N1 of the second pixel drive circuit. In this stage, signals of the first control signal line KS1 and the third scan signal line S3 are low-level signals, and signals of the second control signal line KS2, the first scan signal line S1, the second scan signal line S2 and the light emitting signal line EM are high-level signals, so that the first transistor T1 of each pixel drive circuit and the second transistor T2 of the second pixel drive circuit are turned on and the other transistors are turned off.

The first transistor T1 of each pixel drive circuit is turned on so that a signal of the first initial signal line IN1T1 is provided to the third node N3, to initialize (reset) the third node N3, and clear the original charge in the third node N3, so that the potential of the third node N3 is Vinit1. The second transistor T2 of the second pixel drive circuit is turned on so that the first node N1 and the third node N3 are turned on, to initialize (reset) the first node N1 of the second pixel drive circuit, and clear the original charge in the first node N1, and the potential of the first node N1 is Vinit1. In this stage, the third transistor T3 of the second pixel drive circuit is turned on, and a signal of the second node N2 can be provided to the first node N1 and the third node N3.

In an exemplary implementation mode, the first stage A1, the second stage A2 and the third stage A3 together may be referred to as an initialization stage.

A fourth stage A4 may be referred to as a data writing stage for the first pixel drive circuit. In this stage, signals of the second control signal line KS2 and the first scan signal line S1 are low-level signals, and signals of the first control signal line KS1, the second scan signal line S2, the third scan signal line S3 and the light emitting signal line EM are high-level signals, so that the second transistor T2 of the first pixel drive circuit is turned on, the fourth transistor T4 shared by two pixel drive circuits is turned on, and the other transistors are turned off.

In this stage, since the third transistor T3 is continuously turned on, the second transistor T2 of the first pixel drive circuit is turned on, the fourth transistor T4 is turned on so that a first data signal output from the data signal line DATA is provided to the first node N1 through the second node N2 of the first pixel drive circuit, the turned-on third transistor T3, the third node N3 and the turned-on second transistor T2, and a difference between the first data voltage output from the data signal line DATA and a threshold voltage of the third transistor T3 is charged into the storage capacitor C of the first pixel drive circuit. The voltage of the first node N1 of the first pixel drive circuit is Vd1−|Vth1|, Vd1 is the first data voltage output from the data signal line DATA, and Vth1 is the threshold voltage of the third transistor T3 of the first pixel drive circuit.

A fifth stage A5 may be referred to as a data writing stage for the second pixel drive circuit. In this stage, signals of the first control signal line KS1 and the first scan signal line S1 are low-level signals, and signals of the second control signal line KS2, the second scan signal line S2, the third scan signal line S3 and the light emitting signal line EM are high-level signals, so that the second transistor T2 of the second pixel drive circuit is turned on, the fourth transistor T4 shared by two pixel drive circuits is turned on, and the other transistors are turned off.

In this stage, since the third transistor T3 is continuously turned on and the second transistor T2 of the second pixel drive circuit is turned on, the fourth transistor T4 is turned on so that a second data signal output from the data signal line DATA is provided to the first node N1 through the second node N2 of the second pixel drive circuit, the turned-on third transistor T3, the third node N3 and the turned-on second transistor T2, the difference between a second data voltage output from the data signal line DATA and a threshold voltage of the third transistor T3 is charged into the storage capacitor C of the second pixel drive circuit, the voltage of the first node N1 of the second pixel drive circuit is Vd2−|Vth2|, Vd2 is the second data voltage output by the data signal line DATA, and Vth2 is the threshold voltage of the third transistor T3 of the second pixel drive circuit.

In an exemplary implementation mode, the fourth stage A4 and the fifth stage A5 together may be referred to as a charging stage.

A sixth stage A6 may be referred to as a reset stage for the second node N2, the third node N3, and the fourth node N4. In this stage, signals of the first control signal line KS1, the second control signal line KS2 and the second scan signal line S2 are low-level signals, and signals of the first scan signal line S1, the third scan signal line S3 and the light emitting signal line EM are high-level signals, so that the seventh transistor T7 of each pixel drive circuit is turned on, the eighth transistor T8 shared by two pixel drive circuits is turned on, and other transistors are turned off.

In this stage, since the third transistor T3 is continuously turned on, the seventh transistor T7 is turned on so that a signal of the second initial signal line IN1T2 is provided to the fourth node N4, and the eighth transistor T8 is turned on so that a signal of the third initial signal line IN1T3 is provided to the second node N2 and the third node N3, to reset the second node N2, the third node N3 and the fourth node N4 respectively, potentials of the second node N2 and the third node N3 are Vinit3 and the potential of the fourth node N4 is Vinit2. In this stage, the second node N2, the third node N3 and the fourth node N4 are reset, which can eliminate and improve hysteresis bias due to a difference in gray scales between adjacent pixels, reduce the hysteresis bias, and also periodically reset the anode of the light emitting device to improve the low-frequency flickering.

A seventh stage A7 may be referred to as a light emitting stage. In this stage, signals of the first control signal line KS1, the second control signal line KS2 and the light emitting signal line EM are low-level signals, and signals of the first scan signal line S1, the second scan signal line S2 and the third scan signal line S3 are high-level signals, so that the fifth transistor T5 and the sixth transistor T6 of each pixel drive circuit are turned on and the other transistors are turned off.

The fifth transistor T5 and the sixth transistor T6 are turned on so that a power supply voltage outputted from the first power supply line VDD provides a driving voltage to a first electrode of the light emitting device EL through the fifth transistor T5, the third transistor T3 and the sixth transistor T6 which are turned on to drive the light emitting device EL to emit light.

In a drive process of the pixel drive circuit, a drive current flowing through the third transistor T3 (a drive transistor) of each pixel drive circuit is determined by a voltage difference between a gate electrode and a first electrode of the third transistor T3. Since the voltage of the first node N1 is Vd−|Vth|, the drive current of the third transistor T3 is as follows:

I=K*(Vgs−Vth)²=K*[(Vdd−Vd+|Vth|)−Vth]²=K*[(Vdd−Vd]²

Herein, I is the drive current flowing through the third transistor T3, i.e., a drive current for driving the light emitting device EL, K is a constant, Vgs is the voltage difference between the gate electrode and the first electrode of the third transistor T3, Vth is the threshold voltage of the third transistor T3, Vd is the data voltage output by the data signal line DATA, and Vdd is the power voltage output by the first power supply line VDD.

It can be seen from the derivation results of the above current formula that in the light emitting stage, the drive current of the third transistor T3 of each pixel drive circuit is not affected by the threshold voltage of the third transistor T3. Therefore, the influence of the threshold voltage of the third transistor T3 on the drive current is eliminated, which can ensure uniformity of the display brightness of the display product, and improve the overall display effect of the display product.

The drive method of the display substrate according to this embodiment firstly initializes the first pixel drive circuit and the second pixel drive circuit sequentially, and then charges the first pixel drive circuit and the second pixel drive circuit sequentially, thus realizing the normal operation of each pixel drive circuit. The first control signal line KS1 outputs a turned-on signal in the second stage A2 and the fourth stage A4, the third scan signal line S3 output a turned-on signal in the second stage A2 to initialize the third node N3 of the first pixel drive circuit, and the first scan signal line S1 outputs a turned-on signal in the fourth stage A4 to charge and hold the storage capacitor C of the first pixel drive circuit. The second control signal line KS2 outputs a turned-on signal in the third stage A3 and the fifth stage A5, the third scan signal line S3 outputs a turned-on signal in the third stage A3 to initialize the third node N3 of the second pixel drive circuit, and the first scan signal line S1 outputs a turned-on signal in the fifth stage A5 to charge and hold the storage capacitor C of the second pixel drive circuit.

In the drive method of the display substrate according to this embodiment, the first control signal line KS1 outputs a turned-on signal and a turned-off signal alternately in two times, the second control signal line KS2 outputs a turned-on signal and a turned-off signal alternately in two times, the third scan signal line S3 and the first scan signal line S1 output a turned-on signal sequentially, the initialization of the first pixel drive circuit is completed when the first control signal line KS1 and the third scan signal line S3 output turned-on signals, the initialization of the second pixel drive circuit is completed when the second control signal line KS2 and the third scan signal line S3 output turned-on signals, the charging of the first pixel drive circuit is completed when the first control signal line KS1 and the first scan signal line S1 output turned-on signals, the charging of the second pixel drive circuit is completed when the second control signal line KS2 and the first scan signal line S1 output turned-on signals, and the data signal line sequentially outputs the data voltages of two pixel drive circuits, it is achieved that the data signal line and the fourth transistor T4 shared by the two drive circuits provide a data voltage to the storage capacitor C of each of the pixel drive circuits, respectively, to ensure the normal operation of each of the pixel driving circuits.

In another exemplary implementation mode, the drive method may include following operations.

B21, the first control signal line provides a turned-on signal, the second control signal line provides a turned-off signal, the first compensation transistor is turned on to initialize the first storage capacitor;

B22, the first control signal line provides a turned-on signal, the second control signal line provides a turned-off signal, the first compensation transistor is turned on, and the data signal line provides a first data signal to the first storage capacitor through the data writing transistor, the first drive transistor, and the first compensation transistor;

B23, the first control signal line provides a turned-off signal, the second control signal line provides a turned-on signal, the second compensation transistor is turned on to initialize the second storage capacitor;

B24, the first control signal line provides a turned-off signal, the second control signal line provides a turned-on signal, the second compensation transistor is turned on, and the data signal line provides a second data signal to the second storage capacitor through the data writing transistor, the second drive transistor, and the second compensation transistor.

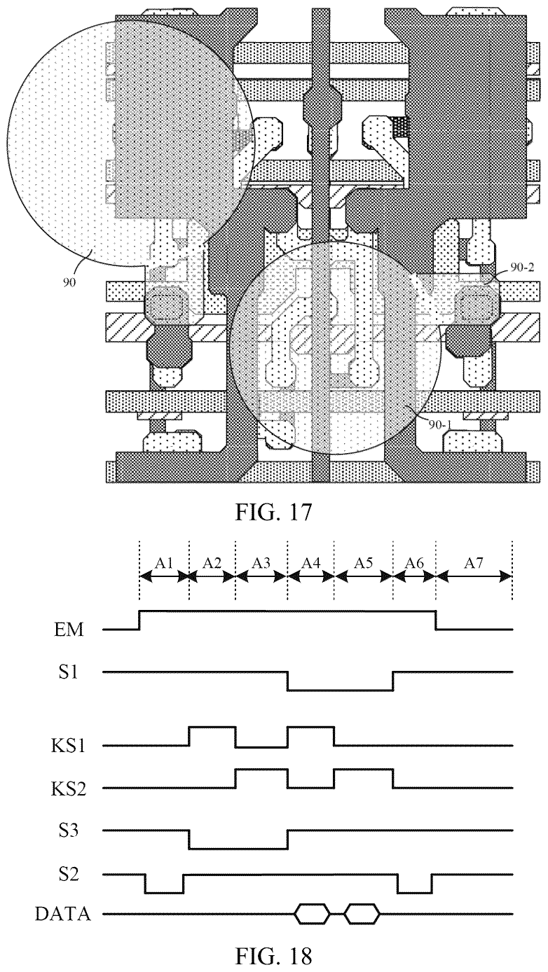

FIG. 19 is another driving timing diagram of a pixel drive circuit according to an exemplary embodiment of the present disclosure. As shown in FIG. 19, the working process of the pixel drive circuit shown in FIG. 4 may include following stages.

A first stage A1 is substantially the same as the first stage A1 of the embodiment shown in FIG. 18, in which the seventh transistor T7 of each pixel drive circuit is turned on, the eighth transistor T8 shared by two pixel drive circuits is turned on, and the other transistors are turned off.

A second stage A2 is substantially the same as the second stage A2 of the embodiment shown in FIG. 18, in which the first transistor T1 of each pixel drive circuit and the second transistor T2 of the first pixel drive circuit are turned on and the other transistors are turned off.

A third stage A3 is substantially the same as the fourth stage A4 of the embodiment shown in FIG. 18, in which the second transistor T2 of the first pixel drive circuit is turned on, the fourth transistor T4 shared by the two pixel drive circuits is turned on, the other transistors are turned off, and the data signal line DATA outputs a first data signal to the first pixel drive circuit.

A fourth stage A4 is substantially the same as the third stage A3 of the embodiment shown in FIG. 18, in which the first transistor T1 of each pixel drive circuit and the second transistor T2 of the second pixel drive circuit are turned on and the other transistors are turned off.

A fifth stage A5 is substantially the same as the fifth stage A5 of the embodiment shown in FIG. 18, in which the second transistor T2 of the second pixel drive circuit is turned on, the fourth transistor T4 shared by the two pixel drive circuits is turned on, the other transistors are turned off, and the data signal line DATA outputs a second data signal to the second pixel drive circuit.

A sixth stage A6 is substantially the same as the sixth stage A6 of the embodiment shown in FIG. 18, in which the seventh transistor T7 of each pixel drive circuit is turned on, the eighth transistor T8 shared by two pixel drive circuits is turned on, and the other transistors are turned off.

A seventh stage A7 is substantially the same as the seventh stage A7 of the embodiment shown in FIG. 18, in which the fifth transistor T5 and the sixth transistor T6 of each pixel drive circuit are turned on and the other transistors are turned off.

The drive method of the display substrate according to this embodiment firstly initializes and charges the first pixel drive circuit, and then initializes and charges the second pixel drive circuit, thus realizing the normal operation of each pixel drive circuit. The first control signal line KS1 outputs a turned-on signal in the second stage A2 and the third stage A3, the third scan signal line S3 outputs a turned-on signal in the second stage A2 to initialize the third node N3 of the first pixel drive circuit, and the first scan signal line S1 outputs a turned-on signal in the third stage A3 to charge and hold the storage capacitor C of the first pixel drive circuit. The second control signal line KS2 outputs a turned-on signal in the fourth stage A4 and the fifth stage A5, the third scan signal line S3 outputs a turned-on signal in the fourth stage A4 to initialize the third node N3 of the second pixel drive circuit, and the first scan signal line S1 outputs a turned-on signal in the fifth stage A5 to charge and hold the storage capacitor C of the second pixel drive circuit.

In the drive method of the display substrate according to this embodiment, the first control signal line KS1 and the second control signal line KS2 output turned-on signals sequentially, the third scan signal line S3 outputs a turned-on signal and a turned-off signal alternately in two times, the first scan signal line S1 outputs a turned-on signal and a turned-off signal alternately in two times, the initialization of the first pixel drive circuit is completed when the first control signal line KS1 and the third scan signal line S3 output turned-on signals, the charging of the first pixel drive circuit is completed when the first control signal line KS1 and the first scan signal line S1 output turned-on signals, the initialization of the second pixel drive circuit is completed when the second control signal line KS2 and the third scan signal line S3 output turned-on signals, the charging of the second pixel drive circuit is completed when the second control signal line KS2 and the first scan signal line S1 output turned-on signals, and the data signal line sequentially outputs the data voltages of two pixel drive circuits, it is achieved that the data signal line and the fourth transistor T4 shared by the two drive circuits provide a data voltage to the storage capacitor C of each of the pixel drive circuits, respectively, to ensure the normal operation of each of the pixel driving circuits.

In yet another exemplary implementation mode, the drive method may include following operations.

B31, the first control signal line provides a turned-on signal, the second control signal line provides a turned-off signal, the first compensation transistor is turned on to initialize the first storage capacitor;

B32, the first control signal line provides a turned-on signal, the second control signal line provides a turned-on signal, the first compensation transistor is turned on to initialize the first storage capacitor, the second compensation transistor is turned on to initialize the second storage capacitor;

B33, the first control signal line provides a turned-on signal, the second control signal line provides a turned-on signal, the first compensation transistor is turned on, the data signal line provides a first data signal to the first storage capacitor through the data writing transistor, the first drive transistor and the first compensation transistor, the second compensation transistor is turned on, the data signal line provides a first data signal to the second storage capacitor through the data writing transistor, the second drive transistor and the second compensation transistor;

B34, the first control signal line provides a turned-off signal, the second control signal line provides a turned-on signal, the second compensation transistor is turned on, and the data signal line provides a second data signal to the second storage capacitor through the data writing transistor, the second drive transistor, and the second compensation transistor.

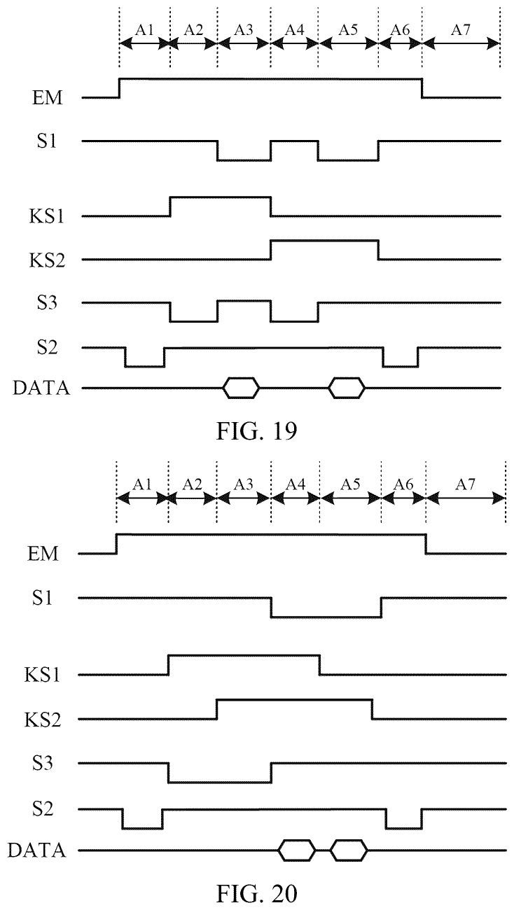

FIG. 20 is yet another driving timing diagram of a pixel drive circuit according to an exemplary embodiment of the present disclosure. As shown in FIG. 20, the working process of the pixel drive circuit shown in FIG. 4 may include following stages.

A first stage A1 is substantially the same as the first stage A1 of the embodiment shown in FIG. 18, in which the seventh transistor T7 of each pixel drive circuit is turned on, the eighth transistor T8 shared by two pixel drive circuits is turned on, and the other transistors are turned off.

A second stage A2 is substantially the same as the second stage A2 of the embodiment shown in FIG. 18, in which the first transistor T1 of each pixel drive circuit and the second transistor T2 of the first pixel drive circuit are turned on and the other transistors are turned off.

A third stage A3 may be referred to as a reset stage for the first nodes N1 of the two pixel drive circuits. In this stage, a signal of the third scan signal line S3 is a low-level signal, and signals of the first control signal line KS1, the second control signal line KS2, the first scan signal line S1, the second scan signal line S2 and the light emitting signal line EM are high-level signals, so that the first transistor T1 and the second transistor T2 of each pixel drive circuit are turned on and the other transistors are turned off.

The first transistor T1 of each pixel drive circuit is turned on so that a signal of the first initial signal line IN1T1 is provided to the third node N3, to initialize (reset) the third node N3, and clear the original charge in the third node N3, so that the potential of the third node N3 is Vinit1. The second transistor T2 of each pixel drive circuit is turned on so that the first node N1 and the third node N3 are turned on, to initialize (reset) the first node N1, and clear the original charge in the first node N1, the potential of the first node N1 is Vinit1. In this stage, the third transistors T3 of the two pixel drive circuits are turned on, and the signal of the second node N2 can be provided to the first node N1 and the third node N3.

A fourth stage A4 may be referred to as a data writing stage for the first pixel drive circuit and the second pixel drive circuit. In this stage, the signal of the first scan signal line S1 is a low-level signal, and signals of the first control signal line KS1, the second control signal line KS2, the second scan signal line S2, the third scan signal line S3 and the light emitting signal line EM are high-level signals, so that the second transistors T2 of the two pixel drive circuits are turned on, the fourth transistor T4 shared by the two pixel drive circuits is turned on, and the other transistors are turned off.

In this stage, since the third transistor T3 is continuously turned on and the second transistors T2 of the two pixel drive circuits are turned on, the fourth transistor T4 is turned on so that a first data signal output by the data signal line DATA is provided to the first node N1 through the second node N2 of each pixel drive circuit, the turned-on third transistor T3, the third node N3 and the turned-on second transistor T2, and the difference between the first data voltage output by the data signal line DATA and the threshold voltage of the third transistor T3 is charged into the storage capacitors C of the two pixel drive circuits, respectively.

A fifth stage A5 may be referred to as a data rewriting stage for the second pixel drive circuit. In this stage, signals of the first control signal line KS1 and the first scan signal line S1 are low-level signals, and signals of the second control signal line KS2, the second scan signal line S2, the third scan signal line S3 and the light emitting signal line EM are high-level signals, so that the second transistor T2 of the second pixel drive circuit is turned on, the fourth transistor T4 shared by the two pixel drive circuits is turned on, and the other transistors are turned off.

In this stage, since the third transistor T3 is continuously turned on and the second transistor T2 of the second pixel drive circuit is turned on, the fourth transistor T4 is turned on so that a second data signal output by the data signal line DATA is provided to the first node N1 through the second node N2 of the second pixel drive circuit, the turned-on third transistor T3, the third node N3 and the turned-on second transistor T2, and the difference between the second data voltage output by the data signal line DATA and the threshold voltage of the third transistor T3 is charged into the storage capacitor C of the second pixel drive circuit. Although the first data voltage is written to two pixel drive circuits in the fourth stage A4 at the same time, since the second transistor T2 of the first pixel drive circuit is turned off in this stage, the storage capacitor C of the first pixel drive circuit holds the first data voltage written in the fourth stage A4, the second transistor T2 of the second pixel drive circuit is turned on, and the storage capacitor C of the second pixel drive circuit is recharged and holds the second data voltage written in the fifth stage A5.

A sixth stage A6 is substantially the same as the sixth stage A6 of the embodiment shown in FIG. 18, in which the seventh transistor T7 of each pixel drive circuit is turned on, the eighth transistor T8 shared by two pixel drive circuits is turned on, and the other transistors are turned off.

A seventh stage A7 is substantially the same as the seventh stage A7 of the embodiment shown in FIG. 18, in which the fifth transistor T5 and the sixth transistor T6 of each pixel drive circuit are turned on and the other transistors are turned off.

In the display substrate according to this embodiment, the first control signal line KS1 and the second control signal line KS2 output a turned-on signal and a turned-off signal in a staggered manner, the third scan signal line S3 and the first scan signal line S1 output turned-on signals sequentially, the initialization of the first pixel drive circuit is completed when the first control signal line KS1 and the third scan signal line S3 output turned-on signals, the initialization of the second pixel drive circuit is completed when the second control signal line KS2 and the third scan signal line S3 output turned-on signals, the charging of the first pixel drive circuit and the second pixel drive circuit is completed when the first control signal line KS1 and the first scan signal line S1 output turned-on signals, and the second pixel drive circuit is recharged when the second control signal line KS2 and the first scan signal line S1 output turned-on signals, and the data signal line sequentially outputs the data voltages of two pixel drive circuits, it is achieved that the data signal line and the fourth transistor T4 shared by the two drive circuits provide a data voltage to the capacitor C of each of the pixel drive circuits, respectively, to ensure the normal operation of each of the pixel driving circuits.

The present disclosure further provides a manufacturing method for a display substrate, for manufacturing the display substrate according to the foregoing embodiments. In an exemplary implementation mode, the display substrate including a plurality of circuit units constituting a plurality of unit rows and a plurality of unit columns, at least one circuit unit at least includes a pixel drive circuit, at least one pixel drive circuit at least includes a data writing transistor connected to a data signal line, the plurality of circuit units at least include a first circuit unit and a second circuit unit adjacent in a unit row direction; the manufacturing method includes:

Forming a first pixel drive circuit in the first circuit unit, forming a second pixel drive circuit in the second circuit unit, the first pixel drive circuit and the second pixel drive circuit share a same data writing transistor and a same data signal line, the data signal line provides a first data signal to the first pixel drive circuit and a second data signal to the second pixel drive circuit through the data writing transistor sequentially.

The present disclosure further provides a display apparatus which includes the aforementioned display substrate. The display apparatus may be any product or component with a display function, such as a mobile phone, a tablet computer, a television, a display, a laptop computer, a digital photo frame, or a navigator, which is not limited in the embodiments of the present disclosure.

Although implementation modes disclosed in the present disclosure are as above, it should be noted that the above implementation modes are only exemplary rather than restrictive. Therefore the present disclosure is not limited to what is specifically shown and described herein. Various modifications, substitutions or omissions may be made to the form and details of implementation without departing from the scope of the present disclosure.

1. A display substrate comprising a plurality of circuit units constituting a plurality of unit rows and a plurality of unit columns, at least one of the circuit units at least comprises a pixel drive circuit, at least one pixel drive circuit at least comprises a data writing transistor connected to a data signal line; the plurality of circuit units at least comprise a first circuit unit and a second circuit unit adjacent in a unit row direction, the first circuit unit comprises a first pixel drive circuit, the second circuit unit comprises a second pixel drive circuit, the first pixel drive circuit and the second pixel drive circuit share a same data writing transistor and are connected to a same data signal line, the data signal line provides a first data signal to the first pixel drive circuit and provides a second data signal to the second pixel drive circuit sequentially through the data writing transistor.

2. The display substrate according to claim 1, wherein an orthographic projection of the data writing transistor on a plane of the display substrate at least partially overlaps with an orthographic projection of a unit dividing line on the plane of the display substrate, and an orthographic projection of the data signal line on the plane of the display substrate at least partially overlaps with an orthographic projection of the unit dividing line on the plane of the display substrate, the unit dividing line is a straight line located between the first circuit unit and the second circuit unit and extending in a unit column direction.

3. The display substrate according to claim 2, wherein the data writing transistor at least comprises a data writing active layer, the data signal line is connected to a first region of the data writing active layer through a data connection electrode, an orthographic projection of the data writing active layer on the plane of the display substrate at least partially overlaps with the orthographic projection of the unit dividing line on the plane of the display substrate, and an orthographic projection of the data connection electrode on the plane of the display substrate at least partially overlaps with the orthographic projection of the unit dividing line on the plane of the display substrate.

4. The display substrate according to claim 3, wherein in a direction perpendicular to the display substrate, the display substrate comprises a plurality of conductive layers sequentially disposed on a base substrate, the data signal line and the data connection electrode are disposed in different conductive layers, the data signal line is connected to the data connection electrode through a first connection via, and an orthographic projection of the first connection via on the plane of the display substrate at least partially overlaps with the orthographic projection of the unit dividing line on the plane of the display substrate.

5. The display substrate according to claim 4, wherein in the direction perpendicular to the display substrate, the display substrate further comprises a first semiconductor layer in which the data writing active layer is disposed, the data connection electrode is connected to the first region of the data writing active layer through a second connection via, an orthographic projection of the second connection via on the plane of the display substrate at least partially overlaps with the orthographic projection of the unit dividing line on the plane of the display substrate.

6. The display substrate according to claim 1, wherein the display substrate further comprises a first control signal line and a second control signal line; the first control signal line is connected to the first pixel drive circuit, the first control signal line is configured such that the data signal line provides the first data signal to the first pixel drive circuit; the second control signal line is connected to the second pixel drive circuit, and the second control signal line is configured such that the data signal line provides the second data signal to the second pixel drive circuit.

7. The display substrate according to claim 6, wherein the first pixel drive circuit further comprises a first compensation transistor and a first drive transistor, the second pixel drive circuit further comprises a second compensation transistor and a second drive transistor, and the data writing transistor is connected to a first electrode of the first drive transistor and a first electrode of the second drive transistor respectively; a gate electrode of the first compensation transistor is connected to the first control signal line, a first electrode of the first compensation transistor is connected to a gate electrode of the first drive transistor, and a second electrode of the first compensation transistor is connected to a second electrode of the first drive transistor; a gate electrode of the second compensation transistor is connected to the second control signal line, a first electrode of the second compensation transistor is connected to a gate electrode of the second drive transistor, and a second electrode of the second compensation transistor is connected to a second electrode of the second drive transistor.

8. The display substrate according to claim 6, wherein the display substrate comprises a plurality of conductive layers sequentially disposed on a base substrate in the direction perpendicular to the display substrate, and the first control signal line and the second control signal line are disposed in a same conductive layer; or
wherein the data writing transistor, the first drive transistor and the second drive transistor are polysilicon transistors, and the first compensation transistor and the second compensation transistor are oxide transistors.

9. (canceled)

10. The display substrate according to claim 1, wherein each pixel drive circuit further comprises a light emitting control transistor, the first pixel drive circuit and the second pixel drive circuit share a same light emitting control transistor, a first electrode of the light emitting control transistor is connected to a first power supply line, and a second electrode of the light emitting control transistor is connected to a second electrode of the data writing transistor.

11. The display substrate according to claim 10, wherein the light emitting control transistor at least comprises a light emitting control active layer, the first power supply line is connected to a first region of the light emitting control active layer through a power supply connection electrode, an orthographic projection of the light emitting control active layer on a plane of the display substrate at least partially overlaps with an orthographic projection of a unit dividing line on the plane of the display substrate, and an orthographic projection of the power supply connection electrode on the plane of the display substrate at least partially overlaps with the orthographic projection of the unit dividing line on the plane of the display substrate.

12. The display substrate according to claim 11, wherein in a direction perpendicular to the display substrate, the display substrate comprises a plurality of conductive layers sequentially disposed on a base substrate, the first power supply line and the power supply connection electrode are disposed in different conductive layers, the first power supply line is connected to the power supply connection electrode through a third connection via which is disposed in the first circuit unit and the second circuit unit respectively.

13. The display substrate according to claim 1, wherein the pixel drive circuit further comprises an initialization transistor, the first pixel drive circuit and the second pixel drive circuit share a same initialization transistor, a first electrode of the initialization transistor is connected to an initial signal line, and a second electrode of the initialization transistor is connected to a second electrode of the data writing transistor.

14. The display substrate according to claim 13, wherein the initialization transistor at least comprises an initialization active layer, a first region of the initialization active layer is connected to the initial signal line, and a second electrode of the initialization transistor is connected to a second electrode of the data writing transistor through an initial connection electrode, an orthographic projection of the initial connection electrode on a plane of the display substrate at least partially overlaps with an orthographic projection of a unit dividing line on the plane of the display substrate.

15. The display substrate according to claim 14, wherein in a direction perpendicular to the display substrate, the display substrate further comprises a first semiconductor layer, the initialization active layer is disposed in the first semiconductor layer, the initial connection electrode is connected to an active layer of the data writing transistor through a fourth connection via, and an orthographic projection of fourth connection via on the plane of the display substrate at least partially overlaps with the orthographic projection of the unit dividing line on the plane of the display substrate.

16. A display apparatus, comprising the display substrate according to claim 1.

17. A drive method of a display substrate, the display substrate comprising a plurality of circuit units constituting a plurality of unit rows and a plurality of unit columns, wherein at least one of the circuit units at least comprises a pixel drive circuit, at least one pixel drive circuit at least comprises a data writing transistor connected to a data signal line; the plurality of circuit units at least comprise a first circuit unit and a second circuit unit adjacent in a unit row direction, the first circuit unit comprises a first pixel drive circuit, the second circuit unit comprises a second pixel drive circuit, the first pixel drive circuit and the second pixel drive circuit share a same data writing transistor and a same data signal line; and the drive method comprises:
the data signal line providing a first data signal to the first pixel drive circuit and providing a second data signal to the second pixel drive circuit through the data writing transistor sequentially.

18. The drive method according to claim 17, wherein the display substrate further comprises a first control signal line and a second control signal line; the first pixel drive circuit further comprises a first compensation transistor, a first drive transistor and a first storage capacitor, a gate electrode of the first compensation transistor is connected to the first control signal line, a first electrode of the first compensation transistor is respectively connected to a gate electrode of the first drive transistor and the first storage capacitor, a second electrode of the first compensation transistor is connected to a second electrode of the first drive transistor, a first electrode of the first drive transistor is connected to the data writing transistor; the second pixel drive circuit further comprises a second compensation transistor, a second drive transistor and a second storage capacitor, a gate electrode of the second compensation transistor is connected to the second control signal line, a first electrode of the second compensation transistor is respectively connected to a gate electrode of the second drive transistor and the second storage capacitor, a second electrode of the second compensation transistor is connected to a second electrode of the second drive transistor, a first electrode of the second drive transistor is connected to the data writing transistor;
the data signal line providing the first data signal to the first pixel drive circuit and providing the second data signal to the second pixel drive circuit through the data writing transistor sequentially comprises:
the first control signal line providing a turned-on signal, the second control signal line providing a turned-off signal, to turn on the first compensation transistor to initialize the first storage capacitor;
the first control signal line providing a turned-off signal, the second control signal line providing a turned-on signal, to turn on the second compensation transistor to initialize the second storage capacitor;
the first control signal line providing a turned-on signal, the second control signal line providing a turned-off signal, to turn on the first compensation transistor, and the data signal line providing the first data signal to the first storage capacitor through the data writing transistor, the first drive transistor, and the first compensation transistor; and
the first control signal line providing a turned-off signal, the second control signal line providing a turned-on signal, to turn on the second compensation transistor, and the data signal line providing the second data signal to the second storage capacitor through the data writing transistor, the second drive transistor, and the second compensation transistor.

19. The drive method according to claim 17, wherein the display substrate further comprises a first control signal line and a second control signal line; the first pixel drive circuit further comprises a first compensation transistor, a first drive transistor and a first storage capacitor, a gate electrode of the first compensation transistor is connected to the first control signal line, a first electrode of the first compensation transistor is respectively connected to a gate electrode of the first drive transistor and the first storage capacitor, a second electrode of the first compensation transistor is connected to a second electrode of the first drive transistor, a first electrode of the first drive transistor is connected to the data writing transistor; the second pixel drive circuit further comprises a second compensation transistor, a second drive transistor and a second storage capacitor, a gate electrode of the second compensation transistor is connected to the second control signal line, a first electrode of the second compensation transistor is respectively connected to a gate electrode of the second drive transistor and the second storage capacitor, a second electrode of the second compensation transistor is connected to a second electrode of the second drive transistor, a first electrode of the second drive transistor is connected to the data writing transistor;
the data signal line providing the first data signal to the first pixel drive circuit and providing the second data signal to the second pixel drive circuit through the data writing transistor sequentially comprises:
the first control signal line providing a turned-on signal, the second control signal line providing a turned-off signal, to turn on the first compensation transistor to initialize the first storage capacitor;
the first control signal line providing a turned-on signal, the second control signal line providing a turned-off signal, to turn on the first compensation transistor, and the data signal line providing the first data signal to the first storage capacitor through the data writing transistor, the first drive transistor, and the first compensation transistor;
the first control signal line providing a turned-off signal, the second control signal line providing a turned-on signal, to turn on the second compensation transistor to initialize the second storage capacitor; and
the first control signal line providing a turned-off signal, the second control signal line providing a turned-on signal, to turn on the second compensation transistor, and the data signal line providing the second data signal to the second storage capacitor through the data writing transistor, the second drive transistor, and the second compensation transistor.

20. The drive method according to claim 17, wherein the display substrate further comprises a first control signal line and a second control signal line; the first pixel drive circuit further comprises a first compensation transistor, a first drive transistor and a first storage capacitor, a gate electrode of the first compensation transistor is connected to the first control signal line, a first electrode of the first compensation transistor is respectively connected to a gate electrode of the first drive transistor and the first storage capacitor, a second electrode of the first compensation transistor is connected to a second electrode of the first drive transistor, a first electrode of the first drive transistor is connected to the data writing transistor; the second pixel drive circuit further comprises a second compensation transistor, a second drive transistor and a second storage capacitor, a gate electrode of the second compensation transistor is connected to the second control signal line, a first electrode of the second compensation transistor is respectively connected to a gate electrode of the second drive transistor and the second storage capacitor, a second electrode of the second compensation transistor is connected to a second electrode of the second drive transistor, a first electrode of the second drive transistor is connected to the data writing transistor;
the data signal line providing the first data signal to the first pixel drive circuit and providing the second data signal to the second pixel drive circuit through the data writing transistor sequentially comprises:
the first control signal line providing a turned-on signal, the second control signal line providing a turned-off signal, to turn on the first compensation transistor to initialize the first storage capacitor;
the first control signal line providing a turned-on signal, the second control signal line providing a turned-on signal, to turn on the first compensation transistor to initialize the first storage capacitor, and to turn on the second compensation transistor to initialize the second storage capacitor;
the first control signal line providing a turned-on signal, the second control signal line providing a turned-on signal, to turn on the first compensation transistor, the data signal line providing the first data signal to the first storage capacitor through the data writing transistor, the first drive transistor and the first compensation transistor, turning on the second compensation transistor, the data signal line providing the first data signal to the second storage capacitor through the data writing transistor, the second drive transistor and the second compensation transistor; and
the first control signal line providing a turned-off signal, the second control signal line providing a turned-on signal, to turn on the second compensation transistor, and the data signal line providing the second data signal to the second storage capacitor through the data writing transistor, the second drive transistor, and the second compensation transistor.

21. A manufacturing method of a display substrate, the display substrate comprising a plurality of circuit units constituting a plurality of unit rows and a plurality of unit columns, wherein at least one of the circuit units at least comprises a pixel drive circuit, at least one pixel drive circuit at least comprises a data writing transistor connected to a data signal line, the plurality of circuit units at least comprise a first circuit unit and a second circuit unit adjacent in a unit row direction; and the manufacturing method comprises:
forming a first pixel drive circuit in the first circuit unit, forming a second pixel drive circuit in the second circuit unit, wherein the first pixel drive circuit and the second pixel drive circuit share a same data writing transistor and a same data signal line, the data signal line provides a first data signal to the first pixel drive circuit and provides a second data signal to the second pixel drive circuit through the data writing transistor sequentially.
